(19) United States
(12) Patent Application Publication
(10) Pub. No.: US 2012/0145146 A1
(43) Pub. Date: Jun. 14, 2012

(54) LIGHT ABSORBING DEVICE

(76) Inventors: Frederic Telander, Bromma (SE); Arne Moberg, Enskede (SE); Per Alvestig, Ekero (SE)

(21) Appl. No.: 13/376,857

(22) PCT Filed: Jun. 18, 2010
(86) PCT No.: PCT/SE2010/050698

§ 371 Date: Feb. 28, 2012

(30) Foreign Application Priority Data
Jun. 18, 2009 (SE) 0950470-5

(51) Int. Cl. F24J 2/04; H01L 31/02; E04D 13/18

(52) U.S. Cl. 126/628; 126/634; 126/646; 126/647; 136/252

(57) ABSTRACT

A light absorbing device for heating a medium by means of solar energy, comprising a first and second layer of which at least one is intended for solar energy absorption, forming a space there between in which a first medium is arranged to flow for said heating, and means arranged to allow said flowing, wherein at least one of said layers is flexible such that the surface exposed for solar energy absorption is reducible. The invention also relates to an at least partly flexible building construction.

### TECHNICAL FIELD

The invention relates to a light absorbing device according to the preamble of claim 1. The invention also relates to a building construction according to claim 28.

### BACKGROUND ART

Light absorbing devices exist in a number of designs. A variant of a light absorbing device is a box-like construction with an outer glass sheet allowing light rays through, wherein a liquid medium is circulated in a pipe system in a substantially confined space underneath the glass sheet, wherein the medium is heated by means of said light rays. Such devices are intended to be stationary placed on house walls/roofs wherein the hot medium may be used for heating the air in the building or for producing hot tap water. Placement of such devices on roofs or walls of houses is aesthetically unattractive. Further pipe systems for transportation of the medium and a pump arranged to circulate the medium are required, resulting in such devices becoming relatively expensive.

WO 02/33331 A1 discloses a light absorber comprising a first layer of light permeable material and a light absorbing layer, on which light let through incides. Underneath the light absorbing layer an air contained space is present, in which the air is heated when light incides against the light absorbing material layer. In the specification an embodiment is suggested in which the light permeable material layer is built up of transparent elements having the same shape as conventional roofing tiles. Hereby a construction which is aesthetically attractive is obtained since it does not depart from the building itself. However, installation of such a stationary device results in relatively large interventions in an existing building and is thus relatively complicated to install.

Further light absorbers according to prior art may be bulky and are generally difficult to transport, difficult to handle, and difficult to assemble. In addition fixed integrated installations remains in the property and is regarded as building accessories.

### OBJECT OF THE INVENTION

An object of the invention is to provide a light absorbing device which facilitates a relatively cheap construction, easy manufacturing and installation, easy application and removal, and easy handling and transportation.

### SUMMARY OF THE INVENTION

These and other objects, apparent from the following description, are achieved by a light absorbing device and a building construction, which is of the type stated by way of introduction and which in addition exhibits the features recited in the characterising clause of the appended claims 1 and 28. Preferred embodiments of the inventive light absorbing device are defined in appended dependent claims 2-27.

According to the invention the objects are achieved with a light absorbing device for heating a medium by means of solar energy, comprising a first and second layer of which at least one is intended for solar energy absorption, forming a space there between in which a first medium is arranged to flow for said heating, and means arranged to allow said flowing, wherein at least one of said layers is flexible such that the surface exposed for solar energy absorption is reducible.

As at least one of the layers is flexible such that the surface exposed for solar energy absorption is reducible a device is obtained which may be rolled up, is foldable, is stowable, is pleatable and/or may be crumpled, which facilitates easier transportation and that the device when stored away takes up little space. The device facilitates a cost efficient construction and manufacturing. Further, easy application and removal such that the device may be mounted where it is most useful, and/or is most energy efficient, i.e. where it receives the best luminescence is facilitated. The device may e.g. be applied on a house wall on a holiday house during e.g. the winter season when the house is not frequently visited, and then during the summer season be packed together and stowed away or alternatively moved to another place where heating of a medium is required such as e.g. a woodshed for drying of wood.

According to an embodiment the light absorbing device comprises at least one inlet opening and at least one outlet opening, wherein said medium is arranged to flow between said inlet opening and said outlet opening. Hereby transportation of the medium in and out of the space is facilitated.

According to an embodiment of the light absorbing device said flowing means comprises an element configuration arranged to divide the space in at least one first subspace comprising said inlet opening and a second subspace comprising said outlet opening. Hereby a more efficient flow and heating of the medium and the provision of self circulation of a gaseous medium is facilitated.

According to an embodiment the light absorbing device comprises a frame element arranged to delimit the space between said first and second layer. Hereby a substantially confined space is provided.

According to an embodiment of the light absorbing device said element configuration comprises at least one confined channel. Hereby separation of said first and second layer by introduction of insertion means for said separation is facilitated.

According to an embodiment of the light absorbing device said frame element comprises at least one confined channel. Hereby efficient separation of said first and second layer by introduction of insertion means for said separation is facilitated. The insertion means may e.g. be constituted by cellular plastic or similar material being used on e.g. ground sheets.

According to an embodiment of the light absorbing device at least one channel of the element configuration and at least one channel of the frame element are in fluid connection with each other. Hereby introduction of a fluid such as e.g. a gaseous fluid such as air or foam, preferably solidifyable foam, is facilitated such that both the frame element and the element configuration constitute spacer means by means of said insertion of fluid. By the use of a gaseous medium only one pump valve member is required for control of pressurization of channels.

According to an embodiment of the light absorbing device said element configuration comprises from said frame element separated elements arranged in such a way in the space that the surface exposed for solar energy is foldably reducible. Hereby said foldable reduction is facilitated with insertion means such as spacer element or fluid inserted in channels of said separate element, or by allowing said separate elements to be solid spacer elements.

According to an embodiment said light absorbing device comprises spacer means for separating said first and second layer. By using spacer means efficient separation of said space during use of the device is facilitated.

According to an embodiment of the light absorbing device said spacer means comprises channel insertion means. Hereby efficient separation during use and by removal easy reduction of the surface exposed for solar energy absorption, and according to a variant folding, rolling up or corresponding is facilitated.

According to an embodiment of the light absorbing device said channel insertion means comprises a gaseous medium, e.g. air, arranged to be introduced and pressurized in at least one channel of the element configuration and/or at least one channel of the frame element. Hereby easy separation of the layers by inflation by means of the gaseous medium of the channels and easy reduction of the surface exposed for solar energy absorption during emptying of the gaseous medium is facilitated.

According to an embodiment of the light absorbing device said channel insertion means comprises spacer elements arranged to be introduced in at least one channel of the element configuration and/or at least one channel of the frame element. This facilitates stable separation of the layers and by removal of the spacer element easy reduction of the surface exposed for solar energy absorption.

According to an embodiment of the light absorbing device said spacer means comprises resilient means. Hereby efficient separation of the layers, and stretching of the surface exposed for solar energy absorption is facilitated.

According to an embodiment of the light absorbing device said resilient means comprises at least one spring member arranged in said space to provide a spring action between a compressed state and an expressed state for separation of first and second layers, wherein the surface exposed for solar energy absorption is reducible at least in said compressed state.

According to an embodiment of the light absorbing device said spring member is ring-shaped, preferably circular. Hereby provision of a web for flowing of the medium having curves in accordance with the shape of the spring members is facilitated such that a more efficient flowing and thus more efficient heating of the medium is obtained.

According to an embodiment the light absorbing device comprises at least two spring members arranged next to each other in said space such that in said compressed state said spring members are foldable over each other for said reduction of the surface exposed for solar energy absorption.

According to an embodiment of the light absorbing device the device is arranged to be attached to a surface having an inclination relative to the horizontal plane, e.g. a wall, wherein the device comprises surface reduction means for reducing the surface exposed for solar energy absorption when the device is attached to said surface. Hereby having the device permanently suspended is facilitated, wherein the surface exposed for solar energy absorption may be reduced when the device is not intended to be used for heating of the medium by means of solar energy.

According to an embodiment of the light absorbing device said surface reduction means comprises a roll device for unrollable rolling up of said surface exposed for solar energy absorption. This is an efficient and aesthetically attractive way of providing said surface reduction with permanent suspension of the device.

According to an embodiment of the light absorbing device said surface reduction means comprises a retracting device for extensible pleatable retraction of said surface exposed for solar energy absorption. This is an efficient and aesthetically attractive way of providing said surface reduction with permanent suspension of the device.

According to an embodiment of the light absorbing device said first medium is a gaseous medium, preferably air. By using a gaseous medium, problems with leakage of liquid is avoided. Further, self circulation is facilitated, which results in that a relatively cheap device may be provided which does not require any pump.

According to an embodiment of the light absorbing device said first medium is a liquid medium, preferably water. Hereby heating of a liquid, e.g. water, for desired use, such as heating of water for e.g. a swimming pool, is facilitated.

According to an embodiment the light absorbing device comprises a second medium separated from said first medium arranged to flow in channels in said space for said heating, between at least one second inlet opening and at least one second outlet opening. Hereby use of a gaseous medium as a first medium and a liquid medium, e.g. water, as a second medium is facilitated, wherein e.g. water for a swimming pool may be heated by means of the device.

According to an embodiment the light absorbing device comprises a transparent third layer arranged externally to the first layer. Hereby insulation is provided wherein the efficiency is increased.

According to an embodiment of the light absorbing device said flowing means comprises an electric device, e.g. a fan device and/or a pump device. Hereby provision of efficient flowing of the medium is facilitated.

According to an embodiment the light absorbing device comprises at least one solar cell element for driving said electric device. Hereby the device may efficiently be utilized for said flowing of the medium without auxiliary energy source.

According to an embodiment the light absorbing device comprises a valve member arranged in connection to said outlet opening to in a first position allow flowing through the outlet opening into a cavity connected to the outlet opening and in a second position prevent flowing through the outlet opening but allowing flowing out of said cavity to the surrounding. Hereby is facilitated to, apart from heating of the gaseous medium, here air, also utilize the light absorbing device such that the air may be heated when required and ventilation of air through cavities, e.g. a room in a building construction may occur when there is a need for this.

According to an embodiment of the light absorbing device ventilation of the cavity via said space is arranged to be provided in said second position of the valve member. This is advantageous when the cavity, e.g. room in a building construction, needs to be ventilated.

According to the invention the objects are also obtained with a building construction which is at least partly flexible, e.g. a tent, comprising a light absorbing device according to any of said embodiments wherein said light absorbing device constitutes at least one wall and/or roof in said building construction. Hereby the tent or the corresponding only needs to be pitched such that the wall and/or roof provided with the light absorbing device is facing the sun.

### DESCRIPTION OF THE DRAWINGS

A better understanding of the present invention will be had upon the reference to the following detailed description when read in conjunction with the accompanying drawings, wherein like reference characters refer to like parts throughout the several views, and in which:

FIG. 1a schematically illustrates a front view of a light absorbing device according to a first embodiment of the present invention, FIG. 1b a cross section A-A and FIG. 1c a cross section B-B of the device in FIG. 1a;

FIG. 2a schematically illustrates a front view of a light absorbing device according to a second embodiment of the present invention, FIG. 2b a cross section A-A and FIG. 2c a cross section B-B of the device in FIG. 2a;

FIG. 3a schematically illustrates a front view of a light absorbing device according to a third embodiment of the present invention, FIG. 3b a cross section A-A and FIG. 3c a cross section B-B of the device in FIG. 3a;

FIG. 4a schematically illustrates a front view of a light absorbing device according to a fourth embodiment of the present invention, FIG. 4b a cross section A-A and FIG. 4c a cross section B-B of the device in FIG. 4a;

FIG. 5a schematically illustrates a front view of a light absorbing device according to a fifth embodiment of the present invention, FIG. 5b a cross section A-A and FIG. 5c a cross section B-B of the device in FIG. 5a;

FIG. 6a schematically illustrates a front view of a light absorbing device according to a sixth embodiment of the present invention, FIG. 6b a cross section A-A and FIG. 6c a cross section B-B of the device in FIG. 6a;

FIG. 7a schematically illustrates a front view of a light absorbing device according to a seventh embodiment of the present invention, FIG. 7b a cross section A-A and FIG. 7c a cross section B-B of the device in FIG. 7a;

FIG. 8a schematically illustrates a front view of a light absorbing device according to a eighth embodiment of the present invention, FIG. 8b a cross section A-A and FIG. 8c a cross section B-B of the device in FIG. 8a;

FIG. 9 schematically illustrates a front view of a light absorbing device according to a ninth embodiment of the present invention;

FIG. 10 schematically illustrates a front view of a light absorbing device according to a tenth embodiment of the present invention;

FIG. 11a schematically illustrates a front view of a light absorbing device according to an eleventh embodiment of the present invention, FIG. 11b a view from above and FIG. 11c a side view of the device in FIG. 11a;

FIG. 12a schematically illustrates a device according to a twelfth embodiment of the present invention, FIG. 12b a view from above and FIG. 12c a side view of the device in FIG. 12a;

FIG. 13 schematically illustrates a front view of a light absorbing device according to a thirteenth embodiment of the present invention;

FIG. 14 schematically illustrates a front view of a light absorbing device according to a fourteenth embodiment of the present invention;

FIG. 15a schematically illustrates a front view of a light absorbing device according to a fifteenth embodiment of the present invention, FIG. 16b a cross section A-A and FIG. 15c a cross section B-B of the device in FIG. 15a;

FIG. 16a schematically illustrates a front view of a light absorbing device according to a sixteenth embodiment of the present invention, FIG. 16b a view from above and FIG. 16c a side view of the device in FIG. 16a;

FIG. 17a schematically illustrates a front view of a light absorbing device according to a seventeenth embodiment of the present invention, FIG. 17b a detail of the light absorbing device according to FIG. 17a and FIG. 17c a detail of a light absorbing device according to the present invention;

FIG. 18a schematically illustrates a perspective view of a building construction according to an eighteenth embodiment comprising a light absorbing device according to an embodiment of the present invention and FIG. 18b a side view of the building construction in FIG. 18a;

FIG. 19 schematically illustrates a perspective view of a light absorbing device according to a nineteenth embodiment of the present invention; and

FIG. 20a-d schematically illustrates a side view of a part of a light absorbing device according to twentieth embodiments of the present invention.

FIG. 21 a schematically illustrates a front view of a light absorbing device according to a second embodiment of the present invention, FIG. 21b a cross section A-A and FIG. 21c a cross section B-B of the device in FIG. 21a.

### DESCRIPTION OF EMBODIMENTS

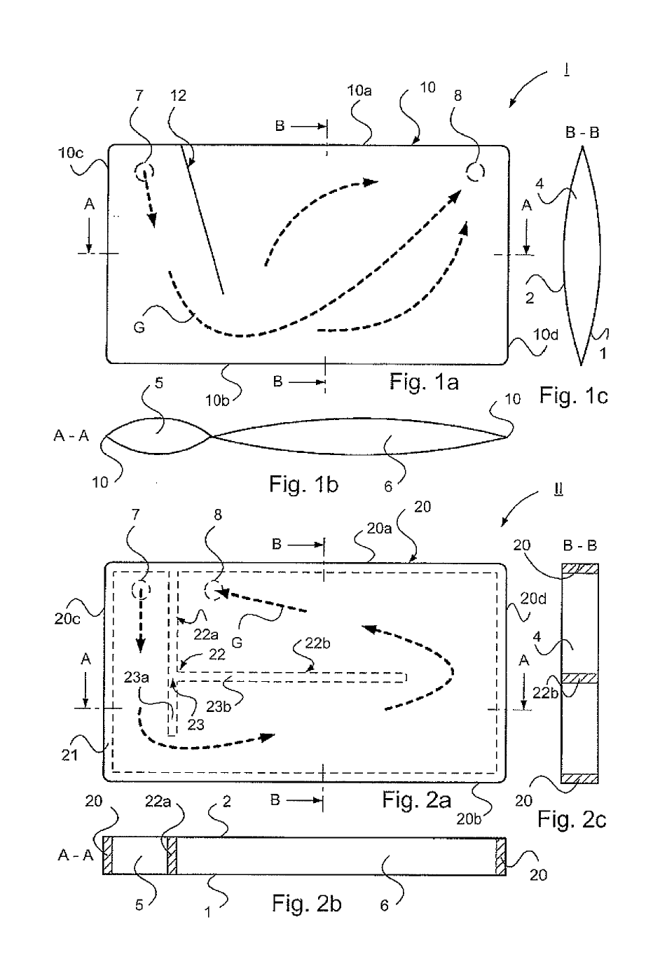

FIG. 1-21 illustrate a light absorbing device according to different embodiments of the present invention.

The light absorbing device for heating a medium G; L by means of solar energy according to the embodiments above comprises a first and second layer 1, 2 of which at least one is intended for solar energy absorption forming a space 4 there between in which a first medium G; L is arranged to flow for said heating, including means arranged to admit said flowing, wherein at least one of said layers 1, 2 is flexible such that the surface exposed to solar energy is reducible.

FIG. 1a-c schematically illustrate a light absorbing device I for heating of a gaseous medium, preferably air, by means of solar energy according to a first embodiment of the present invention.

The light absorbing device I according to the first embodiment comprises a first layer 1 and a second layer 2 connected to the first layer 1 at the edges thereof such that a substantially confined space 4 is formed between them, through which said gaseous medium G is arranged to be flown for said heating. The first and second layers 1, 2 are connected in such a way that said space 4 is formed.

The light absorbing device I is intended during use to be arranged such that the first layer is facing the sun, e.g. arranged on a wall or suspended in another way with a suitable angel to the sun, wherein the device has an upper and a lower portion and upper and lower areas.

According to a variant of the first embodiment both the first and second layers 1, 2 comprise a material with radiation absorbing properties. The first and second layers 1, 2 have according to this embodiment a dark or black surface. When the first layer facing the sun is exposed to solar energy it is heated by solar radiation wherein the gaseous medium G in the space 4 is heated by means of the first layer.

According to another variant the first layer, i.e. the layer intended to be the outer layer facing the sun and consequently arranged to receive solar energy, is of a at least partly transparent material such that light radiation is allowed to pass through the first layer, while the second layer constituting the inner layer comprises a material with radiation absorbing properties. When the first layer facing the sun is exposed to solar energy the solar radiation passes through the first transparent layer wherein the second radiation absorbing layer is heated, which in turn heats up the gaseous medium G in the space 4.

The first and second layers 1, 2 are composed of a flexible material such that the surface exposed to solar energy absorption is reducible, wherein the flexible material is composed such that the first and second layers 1, 2 are rollable, foldable, stowable, pleatable and/or wrinkleable and/or the corresponding.

The first and/or second layers 1, 2 are according to a variant composed of a material with such properties that said space 4, when the light absorbing device I is developed, is substantially maintained. The material of the first and second layers 1, 2 is e.g. textile, fabric, fibre, rubber or the corresponding.

The first and second layers 1, 2 may be connected in any suitable manner. Said connection may e.g. be obtained by the first and second layers 1, 2 being sewed together, glued together, welded together, heated together, connected by means of Velcro fastening, zipper, magnet or the corresponding for forming of said edge. According to a variant said first and second layers are constituted by the same flexible material piece, wherein said material piece is folded such that said first and second layers are formed, wherein a part of said edge or frame is constituted by said outwardly formed pleat.

By said connection at the edges of the first and second layers 1, 2 a surrounding edge or frame/frame element 10 is formed, which frame element 10 constitutes a delimitation of said space 4. The frame element 10 has an upper portion 10a, a lower portion 10b and first and second side portion 10c, 10d.

The light absorbing device I comprises an inlet opening 7 and an outlet opening 8 between which said medium is arranged to be flown. The inlet opening 7 and outlet opening 8 are arranged at a distance from each other in the upper portion of the second layer 2, i.e. the inner layer.

The first and second layers 1, 2 are further connected to each other by means of a connection extending from an upper portion of the frame element 10 in the direction towards and at a distance from a lower portion of the frame element 10. Said connection forms an element configuration 12 constituting partition/guide arranged to divide the space 4 in a first subspace 5 comprising the inlet opening 7 and a second subspace 6 comprising the outlet opening 8 such that the gaseous medium G is only allowed to pass below the lower end of the element configuration. The second subspace 6 has according to this embodiment a larger surface than the first subspace 5.

The element configuration 12 is consequently arranged to guide the gaseous medium G from the inlet opening 7 to the outlet opening 8. Said connection thus forms a guide of the gaseous medium G. The element configuration 12 forms a web in the space 4 extending from the inlet opening 7 to the outlet opening 8. The element configuration 12 has according to this embodiment an inclination such that said web successively increases which facilitates self circulation.

The light absorbing device I comprises connection means for applying the device on a surface having an inclination relative to the horizontal plane, e.g. a house wall, or between to connection points, e.g. a building and a pole or between to trees/poles. The connection means according to a variant comprise suspension devices to which the device is suspended. According to a variant the connection means comprises stretching devices by means of which the device is fastened, such as a console or similar fastener.

The light absorbing device I according to the first embodiment has a substantially rectangular shape. The light absorbing device I may have any shape, such as ring shaped, circular, oval, triangular, pentagonal, or other polygonal shape.

When the gaseous medium G in the space 4 is heated by means of solar energy, i.e. by the sun illuminating the light absorbing device I, any of the first or second subspace 5,6 obtains a slightly higher air temperature. When the air in the space 4 keeps a higher temperature than the building the heated air flows from the subspace having the slightly higher air temperature upwardly and out through the opening of the subspace.

As the second subspace comprising the outlet opening 8 has a larger surface than the first subspace 5 comprising the inlet opening 7 a self circulation is obtained in the space 4 when light heats the gaseous medium G in the space 4 such that a flowing of the gaseous medium G from the inlet opening 7 goes downwardly in the first subspace 5 and flow into the second subspace 6, whereupon the gaseous medium G in the second subspace 6 is flowing towards the outlet opening 8. Thus a thermal unbalance is obtained wherein self circulation in a known manner is facilitated. Hereby a downward flow of the gaseous medium G is obtained and a voluminous upward flow of the gaseous medium G, wherein first/second layer at which the upwardly flowing gaseous medium G is heated has a larger surface such that a smaller flow is obtained and thereby during sun radiation a higher temperature which results in said self circulation.

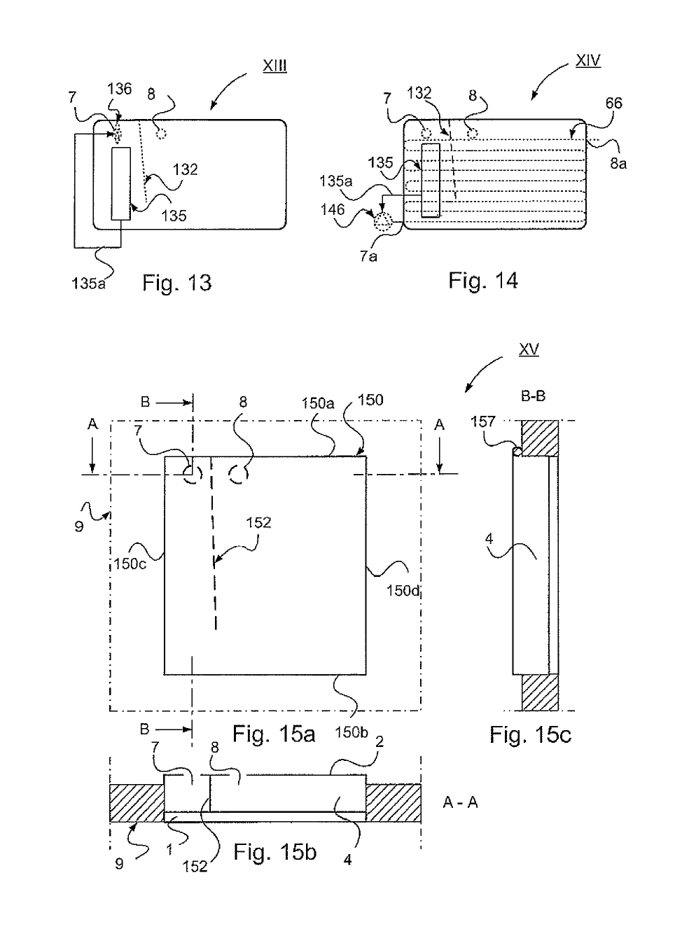

According to a variant the light absorbing device comprises a fan device (not shown—see FIG. 13) for improving the flowing of the gaseous medium G by means of said fan device and also keeping first and second layers separated for providing of said space 4 comprising the first and second subspace 5, 6.

FIG. 2-5 schematically illustrate embodiments of a light absorbing device II; III; IV; V according to a second, third, fourth and fifth embodiment. The embodiments according to FIG. 2-5 differs from the first embodiment in that the frame element 20 comprises spacer means for keeping the first and second layers 1, 2 separated by means of said frame element 20. Further the element configuration 22; 32; 42; 52 constituting the partition/guide of the gaseous medium G comprises spacer means for keeping the first and second layers 1, 2 separated by means of said element configuration 22; 32; 42; 52.

The frame element 20 has an upper portion 20a, a lower portion 20b and a first and second side portion 20c, 20d. According to a variant said frame element 20 comprises a channel 21, wherein said spacer means comprises channel insertion means intended to be arranged in said channel for providing of said separation of the first and second layers 1, 2. Further the element configuration 22; 32; 42; 52 constituting the partition/guide of the gaseous medium G comprises at least one channel/one channel portion 23; 33; 43; 53, wherein said channel insertion means is intended to be arranged in said channel for providing of said separation of first and second layers 1, 2.

According to a variant the channel 21 of the frame element and channel 23; 33; 43; 53 are in fluid connection to each other, forming a channel configuration.

The channel insertion means of said spacer means comprises according to a variant a gaseous medium G, preferably air, wherein the gaseous medium G is arranged to be inserted in at least one of said channels 21, 23; 33; 43; 53 for providing of said separation. According to a variant the spacer means comprises means for pressurising said channel for providing of said separation. The pressurising means comprises according to a variant pump valve means for regulating the pressure in said channel 23; 33; 43; 53.

By pressurising the channel 21 of said frame element 20 by means of a gaseous medium G, preferably air, a relatively stable frame element is obtained, wherein the first and second layers 1, 2 are kept stretched such that the surface exposed for solar energy is fully expanded. By also pressurising the channel 23; 33; 43; 53 of said element configuration 22; 32; 42; 52 a stable device where first and second layers 1, 2 are kept at a distance from each other for providing of said space 4.

Hereby a very flexible material may be used for first layer 1 and/or second layer 2 and at the same time maintain the desired distance between the first and second layers 1, 2. By inflating the channel configuration 21, 23; 33; 43; 53 during use and emptying the channel configuration of the gaseous medium G, preferably air in accordance with an inflatable mattress, for removal, easy deployment for use as a solar collector and easy packing of the device for storing or transport.

According to another variant said channel insertion means of said spacer means comprises spacer elements arranged to be fitted in the channel of the frame and/or element configuration 22; 32; 42; 52 constituting the partition/guide of the gaseous medium G. The channel of the frame and/or element configuration 22; 32; 42; 52 comprises according to an embodiment openings forming pockets (not shown) for insertion of said spacer element. The openings for insertion of spacer elements are according to a variant arranged in connection to each corner of the frame element 20. According to a variant an opening is also arranged in connection to the element configuration 22; 32; 42; 52. According to a variant, openings for insertion of spacer elements are arranged in connection to sides of the frame element 20.

The channels with openings forming pockets are configured in such a way that the spacer elements may be removably arranged in portions of the channel of the frame and/or element configuration 22; 32; 42; 52.

The channel portions are according to a variant configured such that the respective spacer element is prevented from sliding off the same, wherein according to a variant in the channel portion a second pocket is arranged in connection to the respective opening, which is arranged such that the spacer element may be inserted in the channel portion over the same and such that the second pocket then may be pulled over an end portion of the inserted spacer element, i.e. the second pocket has its opening directed substantially opposite to the opening of the channel portion, e.g. in accordance with an inner pocket of a pillow case.

The spacer elements are according to a variant flexible such that they are bendable in such a way that they may be inserted into a channel portion around a corner. Hereby a tension is achieved wherein the first and second layers 1, 2 are kept stretched such that the surface exposed to solar energy is fully expanded. Further the spacer element is kept in place due to said tension wherein no further retaining means are required.

According to a variant spacer elements intended to be arranged in connection to the corners have a curved shape for fitting in channel portions extending around corners of the frame element 20. The spacer elements are according to a variant extruded.

According to a variant the spacer element is of a plastic material. According to a variant the spacer element is shaped as a U-profile, wherein angled cuttings are made in the side pieces, e.g. cuttings of 90 degrees, in order to facilitate forming the profile to a desired angle.

The spacer elements intended to be arranged in channels may be constituted by booms, tubes rolled in woven fabric, e.g. insulation, foam rubber, laths in plastic, wood or the corresponding. The spacer elements are according to a variant filled and pressurized with a gaseous medium such as air.

According to a variant a more permanently developed device is provided by means of a light absorbing device comprising a channel 21, 23; 33; 43; 53 of the frame element 20 and/or element configuration 22; 32; 42; 52 by introducing foam in the channel/channel configuration through e.g. a tube, which foam is allowed to expand in the channel/channel configuration. The required amount of foam may be determined by pre-pressurizing the channel/channel configuration.

The respective channel, channel configuration and/or channel portion is according to a variant constituted by a connection between the first and second layers 1, 2. According to another variant the respective channel, channel configuration and/or channel portion constitute a connection with the first layer or the second layer.

The embodiments according to FIG. 2-5 differ from each other mainly by the shape of the element configuration 22; 32; 42; 52 constituting partition/guide of the gaseous medium G.

FIG. 2a-c schematically illustrate the light absorbing device II according to the second embodiment of the present invention.

The element configuration 22 constituting the partition/guide of the gaseous medium G according to the second embodiment comprising a channel portion 23 comprises a first element 22a in which a first channel 23a is enclosed and a second element 22b in which a second channel 23b is enclosed. The first element 22a has en upper and a lower end. The first element 22a has an extension between its upper end being connected to an upper portion of the frame element 20 and its lower end, which is closed and situated at a distance from a lower portion of the frame element 20. The first element 22a has according to this embodiment a straight extension, i.e. extending substantially perpendicular from the upper portion of the frame element 20, but could alternatively have an inclination. The first element 22a extends according to this embodiment over more than half the distance between upper and lower portion of the frame element 20.

The second element 22b has a first and second end. The second element 22b extends from its first end substantially horizontally and perpendicularly from the first element 22a in the second subspace divided by the first element 22a, i.e. away from the first subspace 5, parallel to and at a distance from the upper portion of the frame element 20 and its second end being closed and situated at a distance from the second side portion 20d of the frame element 20. The second element 22b extends according to this embodiment over more than half of the second subspace 6.

The first element 22a is preferably connected to the upper portion 20a of the frame element 20 such that the first channel 23a is in fluid connection to the channel of the frame element 20. The first element 22a is further preferably connected to the first end of the second element 22b such that the first channel 23a is in fluid connection with the second channel 23b. Thereby only one. pump valve member is required for inflating/emptying said channel configuration for providing of said separation of the first and second layers 1, 2.

The first and second elements 22a, 22b forms an element configuration 22 which constitutes partition/guide for the gaseous medium G and forms a web for the gaseous medium G. The second substantially horizontal element 22b results in the gaseous medium G being forced a longer way from the inlet opening 7 to the outlet opening 8 which results in the gaseous medium G being exposed to more luminescence, and thus better heating is obtained, i.e. a more efficient light absorbing device II compared to the first embodiment.

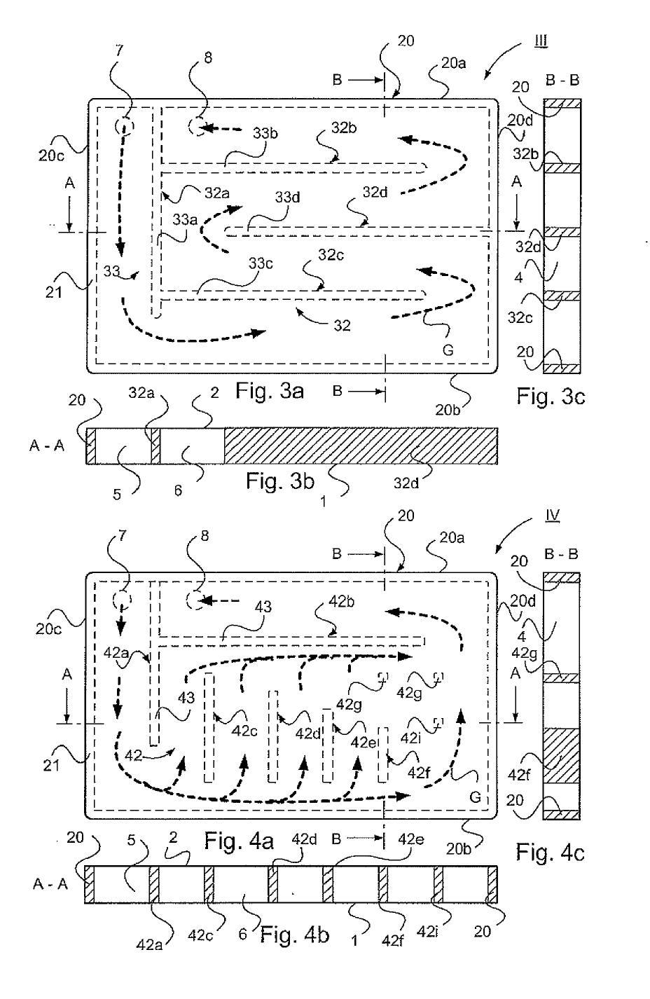

FIG. 3a-c schematically illustrate the light absorbing device III according to the third embodiment of the present invention.

The light absorbing device III according to the third embodiment of the present invention differs from the second embodiment by the element configuration 32, apart from a first element 32a with a first channel 33a, a second element 32b with a second channel 33b, essentially according to the second embodiment, comprising a third element in which a third channel is enclosed and a fourth element in which a fourth channel is enclosed.

The third element 32c has a first and second end. The third element 32c extends as the second element 32b from its first end substantially horizontally and perpendicularly from the first element 32a in the second subspace 6 divided by the first element 32a parallel to and at a distance from the upper portion of the frame element 20 and parallel to and at a distance from the second element 32b between said upper portion of the frame element 20 and second element, and its second end which is closed and situated at a distance from the second side portion of the frame element 20. The third element 32c is according to this embodiment extending over more than half the second subspace 6. The first element 32a is in fluid connection with the third element 32c such that the first channel 33a is in fluid connection with the first end of the third channel 33c.

The fourth element 32d has a first and second end. The fourth element 32d is extending from its first end substantially horizontally and perpendicularly from the second side portion of the frame element 20 in the second subspace 6 divided by the first element 32a, parallel to, between and at a distance from the second and third element 32b, 32c and its other end being closed an situated at a distance from the first element 32a. The fourth element 32d is extending according to this embodiment over more than half of the second subspace 6. The second side portion of the frame element 20 is preferably connected to the first end of the third element 32c such that the channel of the frame element 20 is in fluid connection to the first end of the third channel 33c.

As both the third and fourth channel 33c, 33d are in fluid connection to the remaining channels only one pump valve member is required for inflating/emptying of said channel configuration for providing said separation of the first and second layers 1, 2.

The third and fourth elements 32c, 32d forms together with the first and second elements 32a, 32b an element configuration 32 which constitutes partition/guide for the gaseous medium G and forms a web for the gaseous medium G. The third and fourth substantially horizontal elements 32c, 32d results in the gaseous medium G being forced a longer way from the inlet opening 7 to the outlet opening 8 in comparison to the second embodiment which results in the gaseous medium G for the same flow rate is exposed to luminescence during a longer time and thus better heating is obtained, i.e. a more efficient light absorbing device in comparison to the second embodiment.

FIG. 4a-c schematically illustrate the light absorbing device IV according to the fourth embodiment of the present invention.

The light absorbing device IV according to the fourth embodiment of the present invention differs form the second embodiment in that the element configuration 42, apart from a first element 42a and a second element 42b, essentially according to the second embodiment, comprises elements 42c, 42d, 42e, 42f freestanding from the frame element 20 and the first element 42a, and three freestanding extra elements 42g, 42h, 42i.

The element configuration 42 according to the fourth embodiment comprises four freestanding elements 42c, 42d, 42e, 42f, a first, second, third and fourth freestanding element 42c, 42d, 42e, 42f arranged in the second subspace 6 at a distance from each other and the first element 42a and first and second side portions 20c, 20d of the frame element 20 arranged substantially parallel to the first element 42a and extending between and at a distance from the lower portion 20b of the frame element 20 and the second element 42b from its respective first end to its respective second end.

The distance from the lower portion of the frame element 20 and the first end of the respective freestanding element 42c, 42d, 42e, 42f facing the lower portion 20b of the frame element 20 are essentially the same. The distance from the second end of the respective freestanding element 42c, 42d, 42e, 42f facing the upper portion 20a of the frame element 20 and the second element 42b increases successively from the first freestanding element 42f arranged closest to the side portion of the frame element 20. The freestanding elements 42c, 42d, 42e, 42f extend mainly in the lower area of the second subspace 6. By this arrangement of the freestanding elements 42c, 42d, 42e, 42f a web for the gaseous medium G is obtained with increasing cross sectional area in the flowing direction of the gaseous medium G in the portion between the horizontal second element 42b and the respective second end of the respective freestanding element 42c, 42d, 42e, 42f.

The freestanding extra elements 42g, 42h, 42i are three in number. The first 42g of the extra elements 42g, 42h, 42i is arranged between the second element 42b and the second end of the fourth freestanding element 42f in the extension of the fourth freestanding element 42f. The second 42h of the three extra elements is arranged between the second side portion 20d of the frame element 20 and the first extra element 42g in level with and at a distance from the first extra element 42g and at a distance from the side portion of the frame element 20. The third 42i of the three extra elements is arranged between and at a distance from the lower portion 20b of the frame element 20 and the second extra element 42h. The freestanding extra elements facilitate improved separation of the first and second layers 1, 2.

Said element configuration 42, the freestanding elements 42c, 42d, 42e, 42f and/or the extra elements 42g, 42h, 42i and the frame element 20 may be pressurized by means of a gaseous medium G, wherein several pump valve members are required. Alternatively one or any of said elements may be pressurized with a gaseous medium G, preferably air, wherein e.g. the channel of the frame element 20 and the first channel of the first element 42a, which are in fluid connection with each other, are pressurized by means of a gaseous medium G, while the remaining channels have spacer elements according to above.

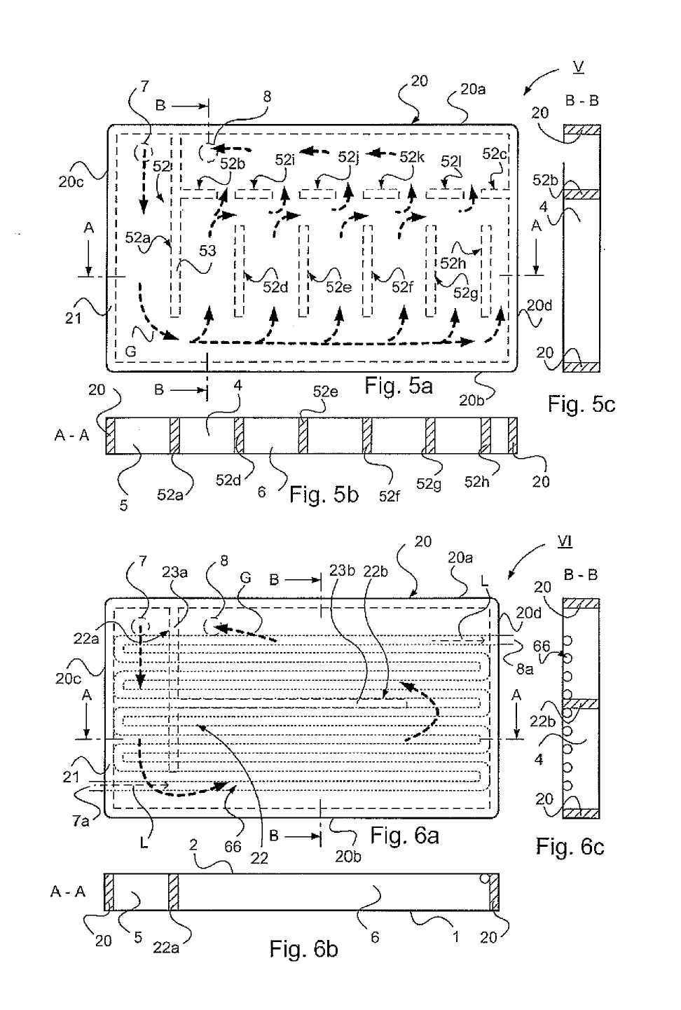

FIG. 5a-c schematically illustrate the light absorbing device V according to the fifth embodiment of the present invention.

The light absorbing device V according to the fifth embodiment of the present invention differs from the second embodiment in that the second element 52b of the element configuration 52 has a substantially horizontal extension from the first element 52a which is less than half the second subspace 6. Further it differs by a third element 52c which has a first end connected to the second side portion 20d of the frame element 20 and a second end, said third element 52c having a substantially horizontal extension from the second side portion 20d of the frame element 20 which is less than half the second subspace 6 and on substantially the same level as the second element 52b. Further it differs in that it comprises elements 52d, 52e, 52f, 52g, 52h, 52i, 52j, 52k, 52l freestanding from the frame element 20 and the first, second and third elements. Said freestanding elements of the element configuration 52 comprises a first set of freestanding elements 52d, 52e, 52f, 52g, 52h and a second set of free standing elements 52i, 52j, 52k, 52l.

The first set is constituted by five freestanding element portions 52d, 52e, 52f, 52g, 52h, a first, second, third, fourth and fifth freestanding element portion 52d, 52e, 52f, 52g, 52h arranged in the second subspace 6 at a distance from each other and the first element and side portion of the frame element 20 substantially parallel to the first element 52a and between and at a distance from the lower portion 20b of the frame element 20 and the second element 52b extending from its respective first end facing the lower portion 20b of the frame element 20 to its respective second end facing the upper portion 20a of the frame element 20.

The distance from the lower portion of the frame element 20 and the first end of the respective freestanding element 52d, 52e, 52f, 52g, 52h of said first set is substantially the same, as well as the distance from the second end of the respective freestanding element and the upper portion of the frame element 20. The freestanding elements 52d, 52e, 52f, 52g, 52h of the first set are extending mainly in the lower area of the second subspace 6.

The second set is constituted by four substantially horizontal freestanding elements 52i, 52j, 52k, 52l, a first, second, third and fourth freestanding element 52i, 52j, 52k, 52l extending at a distance from each other between and at a distance from the second element 52b and the third element 52c, which respectively have a first end facing the first element and a second end facing the second side portion 20d of the frame element 20.

The side of the first freestanding element 52d of the first set of freestanding elements facing the first element 52a is present at substantially the same distance from the first end of the first horizontal freestanding element 52i of the second set of freestanding elements.

The side of the second freestanding element 52e of the first set of freestanding elements facing the first element 52a is present at substantially the same distance from the first end of the second horizontal freestanding element 52j of the second set of freestanding elements.

The side of the third freestanding element 52f of the first set of freestanding elements facing the first element 52a is present at substantially the same distance from the first end of the third horizontal freestanding element 52k of the second set of freestanding elements.

The side of the fourth freestanding element 52g of the first set of freestanding elements facing the first element 52a is present at substantially the same distance from the first end of the fourth horizontal freestanding element 52l of the second set of freestanding elements.

The side of the fifth freestanding element 52h of the first set of freestanding elements facing the first element 52a is present at substantially the same distance from the first end of the third element 52c. Hereby folding of the device is facilitated even when spacer means are arranged in channels of the element configuration 52.

By the freestanding elements arranged according to above it is facilitated to fold a part of the surface exposed for solar energy absorption such that a smaller surface for solar energy absorption is obtained. The device V according to this embodiment is consequently adaptable for e.g. size on a wall, wherein the surface exposed for solar energy absorption may be reduced by folding away a part of the surface such that a device with a smaller surface for solar energy absorption may be suspended.

According to an alternative variant the elements 52d, 52e, 52f, 52g could extend to and be connected, e.g. fluid connected, to the horizontal elements 52i, 52j, 52k, 52l, 52c, respectively.

FIG. 6a-c schematically illustrate the light absorbing device VI according to the sixth embodiment of the present invention.

In accordance with the light absorbing device according to the second embodiment the frame element 20 has an upper portion 20a, a lower portion 20b and a first and second side portion 20c, 20d, and are according to a variant arranged to enclose a channel 21. Further the element configuration 22 has according to the second embodiment a first element 22a with a first channel 23a and a second element 22b with a second channel 23b.

The light absorbing device VI according to the sixth embodiment of the present invention differs from the second embodiment in that apart from the gaseous medium G a liquid medium L, preferably water, is also arranged to flow in the space 4.

The light absorbing device VI according to the sixth embodiment comprises a pipe configuration 66 arranged in the space 4, in which the liquid medium L is arranged to flow. The pipe configuration 66 comprises an inlet opening 7a and an outlet opening 8a between which the liquid medium L is arranged to flow.

The pipe configuration 66 may be made by a hose or the corresponding. The pipe configuration 66 is according to this embodiment, e.g. sewn up in or in connection to the inside of the first layer 1, the surface of the first layer 1 is light absorbing, such that the liquid medium L is heated by means of the solar energy and the heated layer and the heated gaseous medium G. According to an alternative variant, the pipe configuration 66 is arranged, e.g. sewn up in or in connection to the inside of the second layer 2, the surface of the second layer 2 being solar energy absorbing, such that the liquid medium L is heated by means of the solar energy and the heated layer and the heated gaseous medium G. According to a variant the first layer 1 is transparent wherein the liquid medium L is subjected to direct radiation, which results in a more efficient heating of said liquid medium L.

The pipe configuration 66 is according to this embodiment arranged in zigzag over essentially the entire surface in order to obtain as large exposed surface as possible in order to increase the efficiency of the device. The pipe configuration 66 has according to this embodiment a substantially horizontal distribution in the space 4, the inlet opening 7a being arranged in connection to the lower portion of the first side portion 20c of the frame element 20 and the outlet opening being arranged in connection to the upper portion of the second side portion 20d of the frame element 20 and the pipe configuration 66 is configured such that the surface exposed for solar energy absorption is reducible. The pipe configuration 66 is preferably flexible such that said first and/or second layer 1, 2 may be reduced, e.g. folded together or the corresponding.

The device VI according to the sixth embodiment comprises means for allowing said flowing of the liquid medium L. Said flowing means is preferably a pump device, not shown here, see FIG. 14.

An advantage with this embodiment is that heating of a gaseous medium G, e.g. air, may be combined with heating of a liquid medium L, e.g. water, where heating of water may be used for e.g. heating water in a swimming pool.

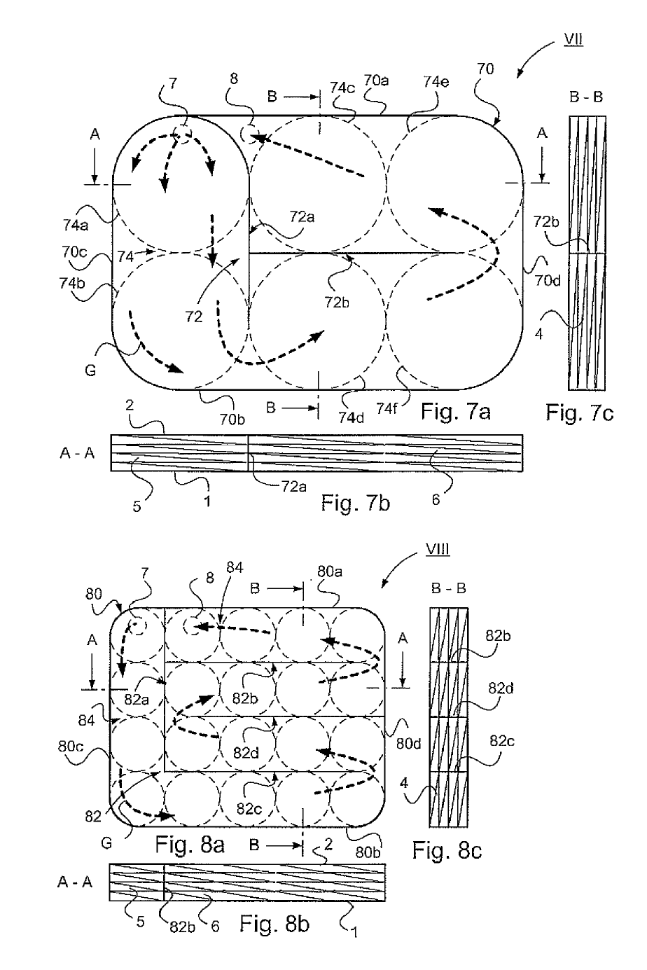

FIG. 7-10 schematically illustrate embodiments of a light absorbing device VII; VIII; IX; X according to a seventh, eight, ninth and tenth embodiment. The embodiments according to FIG. 7-10 differs from the embodiments according to FIG. 2-6 in that said spacer means for keeping the first and second layers 1, 2 separated comprises resilient means 74; 84; 94; 104.

Said resilient means according to FIG. 7-10 are constituted by at least one helical spring. Any type of resilient means such as compression spring members, gas spring members, torsion spring members may be used. Said spring members may be made in any suitable material, e.g. spring steel, metal, composite or the corresponding. Said spring members are according to a variant connected to at least one of the first and second layers 1, 2. According to a variant they are sewn up into the first 1 and/or second layer 2.

Said resilient means 74; 84; 94; 104 are arranged to act between a compressed state and an expanded state. According to a variant they are consequently movable between a biased or compressed state in which the surface exposed for solar energy absorption is reducible, and a sprung or expanded state in which said first and second layers are kept separated for said flowing of the gaseous medium G.

Said spring members 74; 84; 94; 104 according to FIG. 7-10 are according to a variant circular. Said spring members 74; 84; 94; 104 are in the expanded or sprung state arranged to have a stretching effect on the first and second layers 1, 2. According to a variant the spring force of said spring members is so strong that no additional spacer means are required. Hereby reinforcement means such as ropes or the corresponding may be arranged in order to keeping the layers together, the reinforcement means constituting a stroke limiter, i.e. limiting the spring action.

Further the design of the element configuration 72; 82; 102 differs in such a way that the element configuration 72; 82; 102 according to this embodiment has a relatively smaller cross section than the element configuration according to the embodiments in FIG. 2-6. Further the design of the frame element 70; 80; 90; 100 differs in such a way that the frame element 70; 80; 90; 100 according to this embodiment has a thinner cross section than the frame element 70; 80; 90; 100 according to the embodiments in FIG. 2-6. In contrast to the embodiments in FIG. 2-6 neither the element configuration 72; 82; 102 nor the frame element 70; 80; 90; 100 according to this embodiment need to constitute part of spacer means for separation of the first and second layers 1, 2. The element configuration 72; 82; 102 and/or the frame element 70; 80; 90; 100 may be constituted by textile, fabric or corresponding flexible material. The element configuration 72; 82; 102 needs only to have a separating and guiding function, i.e. be arranged to guide the gaseous medium G from the first subspace to the second subspace 6.

FIG. 7a-c schematically illustrate the light absorbing device VII according to a seventh embodiment of the present invention.

The frame element 70 has an upper portion 70a, a lower portion 70b and a first and second side portion 70c, 70d.

The resilient means 74 according to the seventh embodiment comprises a set of six helical spring member 74a, 74b, 74c, 74d, 74e, 74f, a first spring member 74a arranged in the upper area of the first subspace 5, a second spring member 74b arranged next to the first spring member 74a in the lower area of the first subspace 5, a third spring member 74c arranged in the upper area of the second subspace 6 next to the first spring member 74a, fourth spring member 74d arranged in the lower area of the second subspace 6 next to the second spring member 74b, a fifth spring member 74e arranged in the upper area of the second subspace 6 next to the third spring member 74c, and a sixth spring member 74f arranged in the lower area of the second subspace 6 next to the fifth spring member 74e. The first, third and fifth spring members are consequently arranged in a row in the upper area of the space 4, substantially horizontally, and the second, fourth and sixth spring members are arranged in a row in the lower area of the space 4, substantially horizontally. The spring members 74a, 74b, 74c, 74d, 74e, 74f, form a 2×3-matrix.

The frame element 70 is arranged around said set of spring members 74a, 74b, 74c, 74d, 74e, 74f in such a way that it essentially follows the circular shape of the first, second, fifth and sixth spring members such that rounded corners having a radius substantially corresponding to these spring members 74a, 74b, 74e, 74f is obtained.

The first spring member 74a is arranged such that it surrounds the inlet opening 7. The outlet opening 8 is arranged between the first spring member 74a and the second spring member 74b.

The element configuration 72 has essentially the same configuration as the embodiment in FIG. 2, wherein essentially the corresponding flowing of the gaseous medium G is obtained as in the second embodiment.

The first element 72a of the element configuration 72 is arranged to run from its first end connected to the upper portion of the frame element 70 in connection to the upper portion of the first spring member and arranged to run such that it follows a circumferential portion of the first spring member 74a to then run parallel to the first side portion 70c of the frame element 70 its second end substantially at the level where said second and fourth spring members adjoin each other.

The second element 72b of the element configuration 72 is arranged to run substantially horizontally from the first element 72a between the third and fourth spring members 74c, 74d substantially to the adjoining between the fifth and sixth spring members 74e, 74f.

As said set of spring members of the light absorbing device VII according to the seventh embodiment are arranged in a 2×3-matrix according to above the device is foldable at the adjoining between the respective spring member in the compressed or biased state of said set of spring members such that the surface exposed to solar energy absorption is reducible. According to a variant it is foldable between the spring members in the compressed state.

Due to the rounded corners of the frame elements 70 in accordance with quarter of a circle of first, second, fifth and sixth spring members a web is obtained in the space 4 from the inlet opening 7 to the outlet opening 8 having radial curves such that the flowing of the gaseous medium G is facilitated.

FIG. 8a-c schematically illustrate the light absorbing device VIII according to an eight embodiment of the present invention.

The frame element 80 has an upper portion 80a, a lower portion 80b and a first and second side portion 80c, 80d.

The resilient means 84 according to the eighth embodiment comprises a set of helical spring members 84 forming a 4×5-matrix, wherein the first column of four spring members are arranged in the first subspace 5, where the uppermost spring member is arranged to surround the inlet opening 7, and the remaining spring members are arranged in the second subspace 6.

The element configuration 82 has the same configuration as the embodiment according to FIG. 3a-c, wherein essentially the corresponding flowing of the gaseous medium G is obtained as in the third embodiment.

The first element 82a of the element configuration 82a is arranged to run from its first end connected to the upper portion 80a of the frame element 80 parallel to the first side portion 80c of the frame element 80 between the first and second column of said set of spring members to its second end substantially at the level where the second lowest spring member of the first column adjoins the second lowest spring member of the second column.

The second element 82b of the element configuration 82 is arranged to run substantially horizontally from the first element 82a between the spring members in the first and second row being present in the second subspace 6 substantially to the adjoining between the spring members of the first and second row closest to the second side portion 80d of the frame element 80.

The third element 82c of the element configuration 82 is arranged to run substantially horizontally from the first element 82a between the spring members in the third and fourth row substantially to the adjoining between the spring members of the third and fourth row closest to the second side portion of the frame element 80.

The fourth element 82d of the element configuration 82 is arranged to run substantially horizontally from the second side portion of the frame element 80 between the spring members in the second and third row substantially to the adjoining between the spring members of the third and fourth row closest to the first element 82a.

As said set of spring members of the light absorbing device VIII according to the eight embodiment are arranged in a 4×5-matrix according to above, the device is foldable at the adjoinings between the respective spring member in the compressed or biased state of said set of spring member 84 such that the surface exposed for solar energy absorption is reducible.

By means of the rounded corners of the frame element 80 in accordance with the spring member arranged in the respective corner a web is obtained in the space 4 from the inlet opening 7 to the outlet opening 8 which has radial curves such that the flowing of the gaseous medium G is facilitated.

FIGS. 7 and 8 show spring members arranged in sets of matrixes. Any suitable set of matrix, i.e. any suitable number of spring members arranged in matrix formation would be usable.

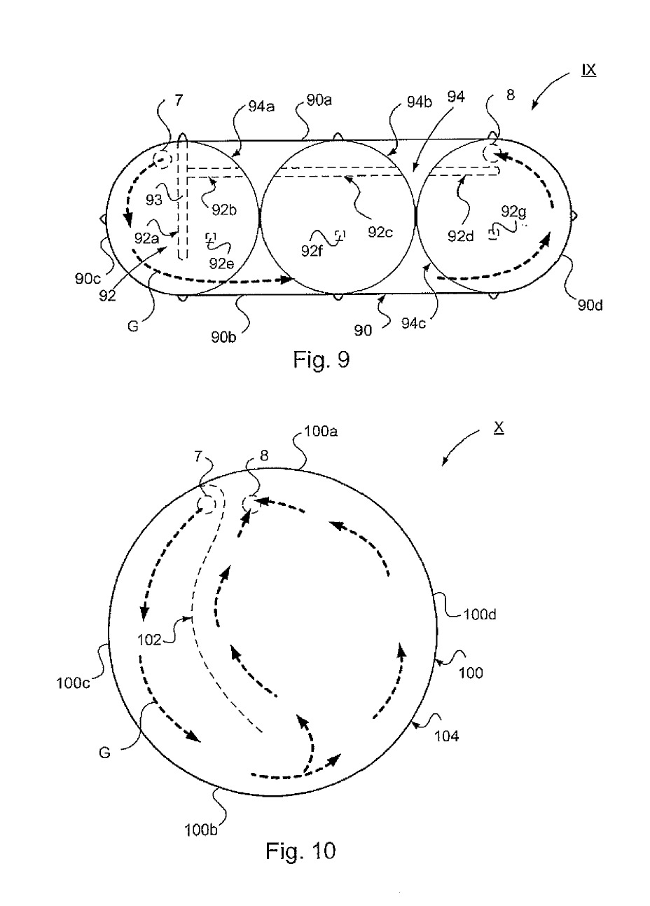

FIG. 9 schematically illustrates a front view of a light absorbing device according to a ninth embodiment of the present invention.

The frame element 90 has en upper portion 90a, a lower portion 90b and a first and second side portion 90c, 90d.

The resilient means 94 according to the ninth embodiment comprises a set of three helical spring members 94a, 94b, 94c, a first, second and third spring member, arranged in a row next to each other in said space 4.

The frame element 90 is arranged around said set of spring members 94a, 94b, 94c in such a way that it essentially follows the circular shape of the first, and third spring member such that the first side portion 90c of the frame element 90 essentially has a semi-circular shape according to the first spring member 94a and the second side portion 90d of the frame element 90 essentially has a semi-circular shape according to the third spring member 94c.

The first spring member 94a is arranged such that it surrounds the inlet opening 7 and the third spring member 94c is arranged such that it surrounds the outlet opening 8.

The element configuration 92 according to this embodiment differs from the embodiments according to FIG. 7-8 in that it comprises channels 93 and the elements 92a, 92b, 92c of the element configuration 92 consequently have a wider cross section than the elements of the embodiments according to FIG. 7-8. Hereby use of the element configuration 92 as spacer element according to FIG. 2-6 is facilitated.

The first element 92a has an extension between its upper end being connected to the upper portion 90a of the frame element 90 essentially in connection to the upper portion of the first spring member 94a and its lower end, being closed and situated at a distance from the lower portion 90b of the frame element 90.

The second element 92b is extending from its first end essentially horizontally and perpendicularly from the first element 92a in the upper area of the second subspace divided by the first element 92a, parallel to and at a distance from the upper portion 90a of the frame element 90 and its second end being closed and situated in connection to an edge portion of the first spring member 94a.

The element configuration 92 further comprises a first and second element 92c, 92d freestanding from the frame element 90 and the first and second elements. The first freestanding element 92c is extending from its first end substantially horizontally and substantially at the same level as the second element 92b between a first channel portion and a second opposite edge portion of the second spring member. The second freestanding element 92d is extending from its first end substantially horizontally and substantially at the same level as the second element 92b and the first freestanding element 92c between a first edge portion and a second opposite edge portion of the third spring member 94c. Hereby use of the element configuration 92 as spacer element according to FIGS. 4 and 5 is facilitated.

The device according to this embodiment in addition comprises extra spacer elements 92e, 92f, 92g in the form of three spacer blocks arranged in the lower portion of the respective spring member in order to further improve separation of first and second layers.

As said spring members 94a, 94b, 94c of the light absorbing device IX according to the ninth embodiment is arranged in a row with freestanding elements according to above the device in the unsprung state of said spring member is foldable at the adjoining between the respective spring member such that en surface exposed for solar energy absorption is reducible. According to a variant it is compressible/foldable to a surface size of only one spring member.

By means of the semi-circular shape of the first and second side portion 90c, 90d of the frame element 90 in accordance with first and third spring members a web is obtained in the space 4 from the inlet opening 7 to the outlet opening 8 having radial curves such that the flowing for the gaseous medium is facilitated.

FIG. 10 schematically illustrates a front view of the light absorbing device X according to the tenth embodiment of the present invention.

The frame element 100 has an upper portion 100a, a lower portion 100b and a first and second side portion 100c, 100d.

The resilient means 104 according to the tenth embodiment comprises a helical spring member, wherein the frame element 100 is arranged around said spring member such that a substantially round or circular device is obtained.

The element configuration 102 according to this embodiment is constituted by an element 102 having a first end connected to an upper portion of the frame element 100 and a lower end being arranged at a distance from a lower edge portion 100b of said frame element 100. The element has a reversed S-shaped shape such that the gaseous medium G is given a favourable guidance.

As the frame element 100 is circular in accordance with the spring member a web is obtained in the space 4 from the inlet opening 7 to the outlet opening 8 having radial curves such that the flowing for the gaseous medium G is facilitated.

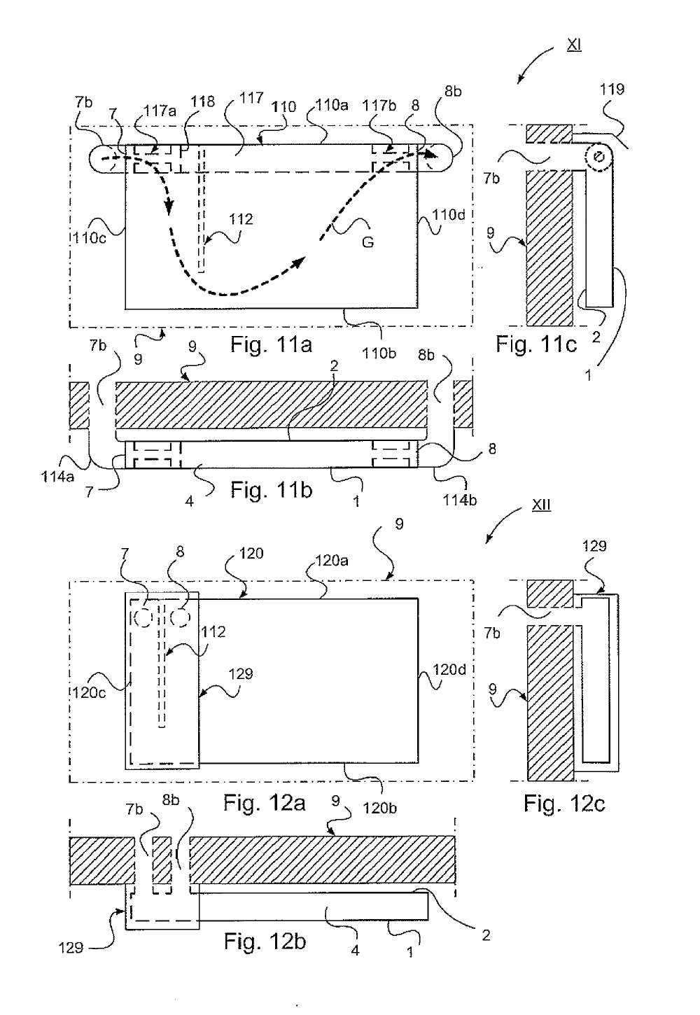

FIG. 11a-c schematically illustrate the light absorbing device XI according to an eleventh embodiment of the present invention.

The frame element 110 has an upper portion 110a, a lower portion 110b and a first and second side portion 110c, 110d. The frame element 110 preferably has a substantially rectangular shape.

The light absorbing device XI according to the eleventh embodiment is intended to be arranged on the wall of a building. The device is intended for more permanent suspension.

The light absorbing device XI according to the eleventh embodiment comprises means for in a deployed position reducing the surface exposed to solar energy, and more specifically means for rolling up the part of the device intended for heating of a medium, consequently comprising first and second layers and element configuration 112. The up-rolling means comprises a roll 117 which is rotatably arranged for said rolling up.

The roll 117 has a first and second end, the first end having an opening constituting the inlet opening 7, and the second end having an opening constituting the outlet opening 8.

The roll 117 is rotatably arranged relative to the inlet opening 7 and outlet opening 8. The inlet opening 7 is arranged to be connected by means of a first pipe sleeve 114a or corresponding first gas connection member for transport of a gaseous medium G, e.g. air, which connection in turn is intended to be connected to an opening 7b in the wall 9. The outlet opening 8 is arranged to be connected by means of a second pipe sleeve 114b or corresponding second gas connection member for transport of a gaseous medium G, e.g. air, which connection in turn is intended to be connected to an opening 8b in the wall 9. According to a variant said first pipe sleeve 114a is connected via a swivel connection to a first sleeve 117a having a stop 118, wherein opening 7 are provided in the sleeve for inlet of a gaseous medium G in the first subspace 5. Further said second sleeve pipe 114b according to a variant is correspondingly connected via a swivel connection to a second sleeve 117b having opening 8 for discharging of the gaseous medium G heated in the space 4.

By connecting the roll 117 with a first and second pipe sleeve 114a, 114b according to above the first and second pipe sleeve 114a, 114b constitute suspension device/fastener for the device.

The part of the device intended for heating of a medium is according to a variant arranged to be rolled up like an awning when the light absorbing device XI is not to be used. Said up-rolling means of the light absorbing device XI according to the eleventh embodiment consequently further comprises means for rotating said roll. Said rotating means comprises according to a variant a manual crank (not shown). According to another variant said rotating means comprises a rope device arranged for said rotation. According to yet another variant said rotational means comprises a motor arranged for said rotation.

The rolling up of the part intended for heating of a medium consequently occurs in a direction upwards.

The light absorbing device XI according to the eleventh embodiment comprises a projecting protection 119 intended to be arranged above said roll for protecting the same and the part of the device intended for heating of a medium.

The part of the light absorbing device XI intended for heating of a medium such as a gaseous medium G, e.g. air, and/or a liquid medium L, e.g. water, may comprise frame element 110 and element configuration 112 according to any of the embodiments in FIG. 1-6, the spacer element according to a variant comprising a gaseous medium G such as air for pressurizing of channels, wherein by rolling up of the part of the device intended for heating of a gaseous medium G, the pressurized/inflated channels are discharged of air in order to facilitate said rolling up.

By means of such a device the light absorbing device XI does not need to be dismantled when not in use but is instead rolled up wherein use of the device is simplified.

The light absorbing device according to the eleventh embodiment is in an active position or operating position rolled out for solar energy absorption and in a passive position or non-operating position rolled up by means of rolling up of the flexible first and second layers wherein the surface exposed for solar energy absorption is reduced in the passive position. By such a device partly rolling up of the first and second layers is also facilitated and thus the surface exposed for solar energy absorption is partly exposed. Hereby varying of the surface exposed for solar energy absorption is facilitated.

FIG. 12a-c schematically illustrate the light absorbing device XII according to a twelfth embodiment of the present invention.

The frame element 120 has an upper portion 120a, a lower portion 20b and a first and second side portion 120c, 120d. The frame element 120 preferably has a substantially rectangular shape.

The light absorbing device XII according to the twelfth embodiment is intended to be arranged on a wall of a building. The device is intended for more permanent suspension.

The light absorbing device XII according to in a stretched position the twelfth embodiment comprises means for reducing the surface exposed for solar energy, and more specifically means for extensibly pleatingly retracting the part of the of the device intended for heating of a medium, comprising first and second layers 1, 2 and where applicable element configuration 112. The means for extending and retracting comprises a pull-wire for said retraction and extension. Alternatively or in addition thereto said means for retracting or extending could comprise a motor for providing and controlling of said retraction and extension.

The part of the device intended for heating of a medium is according to a variant arranged such that when the light absorbing device XII is not to be used it is pulled together in accordance with pulling together of a curtain.

The light absorbing device XII according to the twelfth embodiment further comprises a house 129 intended to be arranged on the wall 9 for receiving the part of the device intended for heating of a medium, wherein during pulling together the part of the device intended for heating of a medium is arranged to be pleatably retracted into said house 129. The house according to a variant has the same appearance as the wall on which it is arranged, wherein in the light absorbing device XII may be camouflaged when it is not being used. The house could according to a variant have a door essentially constituting the external surface, such that during use of the light absorbing device XII for heating by means of solar energy the door may be opened away from the surface exposed for solar energy absorption, wherein substantially the entire the surface exposed for solar energy absorption of the device may be used.

The inlet opening 7 and outlet opening 8 are arranged such that they are present in the house such that pipe sleeve or corresponding connection for transport of a gaseous medium may be permanently connected, and for facilitating retraction.

In FIG. 12 the house 129 is arranged on the left side of the surface exposed for solar energy absorption of the device, wherein said retraction occurs from right to left. Alternatively the house is arranged on the right side of the surface exposed for solar energy absorption, wherein said retraction occurs from left to right. Alternatively the house is horizontally arranged, preferably in the upper area, wherein said retraction occurs upwardly from the bottom.

The part of the light absorbing device XI intended for heating of a medium such as a gaseous medium G, e.g. air, and/or a liquid medium L, e.g. water, may comprise frame element 120 and element configuration 112 according to any of the embodiments in FIG. 1-6, the spacer element according to a variant comprising a gaseous medium G such as air for pressurizing of channels, wherein by rolling up of the part of the device intended for heating of a gaseous medium G, the pressurized/inflated channels are discharged of air in order to facilitate said rolling up.

By means of such a device the light absorbing device XII does not need to be dismantled when not in use but is instead pulled together wherein use of the device becomes more flexible.

The light absorbing device according to the twelfth embodiment is in an active position or operating position extended for solar energy absorption and in a passive position or non-operating position extracted by means of extraction of the flexible first and second layers wherein the surface exposed for solar energy absorption is reduced in the passive position. By such a device partly extracting the first and second layers is also facilitated and thus the surface exposed for solar energy absorption is partly exposed. Hereby varying of the surface exposed for solar energy absorption is facilitated.

FIG. 13 schematically illustrates a front view of the light absorbing device XIII according to the thirteenth embodiment of the present invention and FIG. 14 a front view of the light absorbing device XIV according to the fourteenth embodiment of the present invention.

The light absorbing device according to the thirteenth and fourteenth embodiments of the present invention comprises a preferably flexible solar cell element 135 for generation of electricity exposed on the surface for solar energy absorption, wherein desired electrically operable device may be operated by means of said solar cell element, e.g. a device for providing of flowing of a medium in said space 4 of the light absorbing device. One or more solar cell elements 135 may be used. The light absorbing device according to FIGS. 13 and 14 may be any light absorbing device comprising element configuration 132 and/or spacer means according to any of the embodiments of the present invention.

Preferably said solar cell element 135 is arranged in connection to the first space 5, where the gaseous medium G has the lowest temperature, wherein the heating in the second space 6 is not affected. On the other hand this application may have a favourable effect on the heating of the gaseous medium during flowing of the first space 5 when the gaseous medium cools the solar cell.

FIG. 13 shows the light absorbing device XIII according to the thirteenth embodiment, comprising solar cell elements 135, and a fan device 136, wherein said solar cell element is connected to the fan via a link 135a for providing of said flowing of a gaseous medium G, e.g. air, from the inlet opening 7 to the outlet opening 8.

FIG. 14 shows the light absorbing device XIV according to the fourteenth embodiment, comprising solar cell elements 135, and a pump device 146, wherein said solar cell element 135 is connected to the pump device 146 via a link 135a for providing of said flowing of a liquid medium L, e.g. water, from the inlet opening 7 to the outlet opening 8.

FIG. 15a-c schematically illustrate the light absorbing device XV according to the fifteenth embodiment of the present invention. This device is intended for heating of a gaseous medium G, preferably air.

The light absorbing device XV according to the fifteenth embodiment differs from embodiments mentioned earlier among others in the shape of the first and second layers 1, 2. According to this embodiment the first layer 1 is transparent and rigid and is preferably constituted by glass. The first layer 1 is according to a variant of this embodiment constituted by a window on a building.

The second layer 2 is intended for solar energy absorption and is flexible such that the surface exposed for solar energy absorption is reducible.

The light absorbing device XV comprises means for reducing the surface exposed for solar energy absorption of the second layer 2. Said means comprises according to a variant a window shade type rolling device 157 wherein said second layer, when the device XV is not to be used for heating of the gaseous medium G is arranged to be rolled up by means of the rolling device 157 such that it does not block the view through the first layer, e.g. window. The rolling device 157 comprises a roll about which said second layer may be rolled up.

According to a variant the space 4 is confined by said first and second layers 1, 2 and a portion of the wall portion constituting the window opening projecting out from the window in the direction towards the second layer forming a lower surface 150b, i.e. a window-sill, an upper surface 150a, and first and second surfaces 150c, 150d, wherein said portion of the wall opening constitutes the frame element 150 and spacer means. Alternatively or in addition thereto the light absorbing device XV comprises spacer elements for forming of the frame element 150.

The second layer has an inlet opening 7 and an outlet opening 8 between which the gaseous medium G, e.g. air is intended to flow.

The element configuration 152 according to this embodiment may be constituted by any suitable element, or element configuration 152 for dividing the space 4 between the transparent rigid first layer and the flexible second layer. According to a variant the element configuration 152 comprises a projecting element 152 connected to the second layer and substantially perpendicular to the surface exposed for light absorption, i.e. the surface of the second layer facing the first layer. Said element 152 is arranged to extend from an upper end at the first portion 150a of the frame element 150, to e.g. said upper surface of the portion of the wall opening, to a lower end at a distance from the lower portion 150b of the frame element 150, e.g. said lower surface of the portion of the wall opening. The element 152 is according to a variant flexible in such a way that it is outwardly resiliently pleatable to the second layer 2 and may be rolled up on the roll device 157 together with the second layer 2. The element 152 is according to a variant made of a rubber like material.

The light absorbing device XV according to the fifteenth embodiment further comprises fasteners for connecting and removably fixing the second layer during heating of the gaseous medium G, e.g. the air. Said fastener may be constituted by any suitable fastener for fixing the second layer 2 to the frame element 150 for providing of the substantially closed space 4 for facilitating of said flowing of the gaseous medium G, e.g. air. The fastener may e.g. comprise a Velcro© fastener arranged for said connection. Alternatively or in addition thereto the fastener comprises a zipper for said connection. Alternatively or in addition thereto the fastener comprises magnetic members for magnetic connection.

Such a device results in an easy installation and demands no interference on the wall. By means of such a device the light absorbing device XV does not need to be dismantled when it is not to be used but the second layer is rolled up wherein use of the device becomes more flexible.

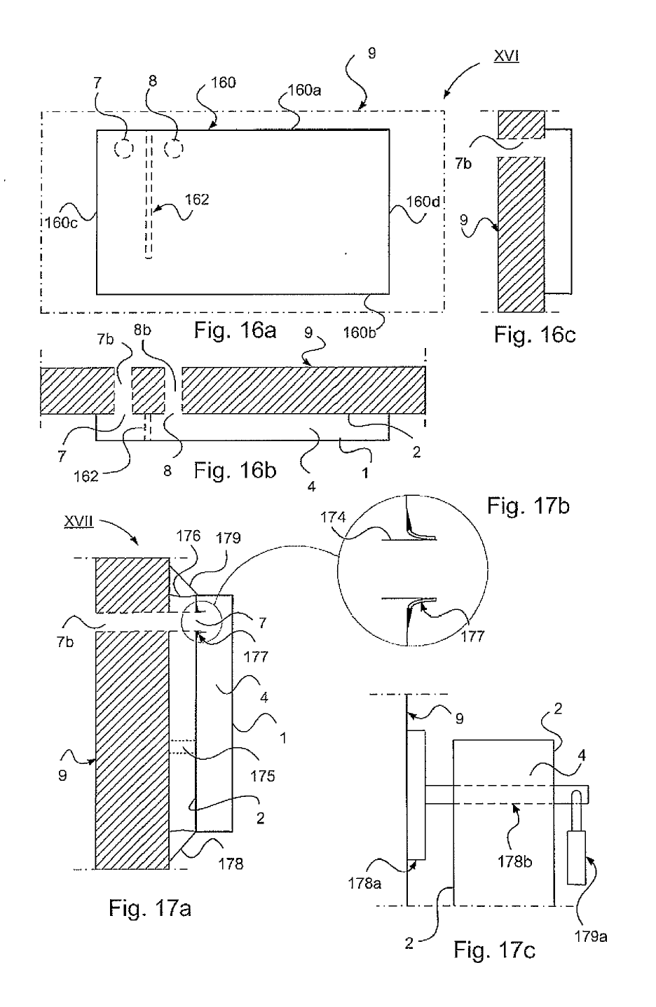

FIG. 16a-c schematically illustrate the light absorbing device XVI according to the sixteenth embodiment of the present invention.

The light absorbing device XVI according to the sixteenth embodiment differs from earlier mentioned embodiments among others in the shape of the first and second layers 1, 2. According to this embodiment the second layer 2 is rigid and is preferably constituted by a wall of a building.

The first layer 1 is intended for solar energy absorption and is flexible such that the surface exposed for solar energy is reducible.

The inlet opening 7 and an outlet opening 8 are here constituted by the openings in the wall 9, between which openings the gaseous medium G, e.g. air is arranged to flow.

The element configuration 162 according to this embodiment may be constituted by any suitable element, or element configuration 162 for dividing the space 4 between the flexible first layer and the rigid second layer, e.g. the wall 9. The element configuration 162 may be constituted by any element configuration 162 according to above described embodiments, such as elements provided with channel for inflating or insertion of spacer elements. The element configuration 162 is preferably connected to the first layer.

The frame element 160 has en upper portion 160a, a lower portion 160b and a first and second side portion 160c, 160d. The frame element 160 may be constituted by any frame element 160 according to embodiments described above, such as frame elements 160 provided with channel for inflating or insertion of spacer elements. The frame element 160 is preferably connected to the first layer.

The spacer elements may be constituted by any spacer element according to above, such as said frame element 160 and/or element configuration 1, and/or resilient means, such as the resilient elements according to FIG. 7-10. Said spacer means/spacer elements are preferably connected to the first layer.

The light absorbing device XVI according to the sixteenth embodiment further comprises fasteners for connecting and removably fixing the device, i.e. second layer and/or frame element 160 to the wall 9 for heating of the gaseous medium G, e.g. air. According to a variant, said fasteners constitute at least a part of a suspension device for suspension of said device on the wall 9. Said fasteners may be constituted by any suitable fastener for fixing the first layer to the frame element 160 for providing of the substantially closed space 4 for facilitating of said flowing of the gaseous medium G, e.g. air. The fastener may e.g. comprise Velcro© fasteners arranged for said connection. Alternatively or in addition thereto the fastener comprises a zipper for said connection. Alternatively or in addition thereto the fastener comprises magnetic members for magnetic connection. Said fastener may be permanently or removably arranged on the wall 9.

Such a device results in an easy installation and demands no interference on the wall. By means of such a device the light absorbing device XVI does not need to be dismantled when it is not to be used but the second layer is rolled up wherein use of the device becomes more flexible.

FIG. 17a schematically illustrates a front view of a light absorbing device according to a seventeenth embodiment of the present invention. The light absorbing device XVII according to this embodiment could be constituted by any of the embodiments according to the present invention being suitable for suspension/application on a wall.

The light absorbing device XVII comprises spacer member 175 such that when suspended the device is arranged at a distance from the wall 9 such that moist and/or mould attacks are avoided. The distance from the wall 9 preferably is relatively short, in the range of 0-300 mm, and partly depends on the shape of the building.

According to a variant the light absorbing device XVII according to the present invention comprises sealing means 176 for sealing the space 4 formed between wall and second layer. According to a variant said sealing means 176 comprises a cover arranged to cover at least the respective side of the space 4. Thereby cooling of the device by air blowing between the device and the wall 9 is avoided. The sealing means 176 results in a heating effect which increases the efficiency of the light absorbing device XVII according to the present invention.

According to a variant the light absorbing device XVII comprises means for connecting inlet opening 7 and outlet opening with a pipe sleeve 174 or corresponding connecting member with a respective opening in the wall 9. According to a said connecting means comprises a flexible membrane 177, e.g. a silicon rubber membrane, arranged in connection to the inlet opening 7 and outlet opening for said connection. The membrane 177 is fixed to the inlet and outlet opening covering a part of the opening and configured to resiliently flare when a pipe sleeve 174 is pressed into the opening such that is sealingly encloses the pipe sleeve 174, see FIG. 17b.

According to a variant the light absorbing device XVII comprises connecting means 178 for applying the device on an angled/inclined surface e.g. a house wall such as illustrated in FIG. 17a, or between two points of attachment, e.g. a building and a pole or between two trees/poles. The connecting means according to a variant comprises suspension devices to which the device is suspended. According to a variant the connecting means comprises stretching devices by means of which the device is fixedly stretched.

According to a variant the light absorbing device XVII comprises locking means 179 for locking the device to a wall or a surface at which the device is suspended/applied, such that the device becomes difficult to remove and consequently difficult to steel. The locking means 179 may be constituted by any suitable locking mechanism.

FIG. 17c shows a detail of the light absorbing device according to FIG. 17a. According to this variant the connecting means comprises stretching devices in the form of a fastener such as a consol device 178a by means of which the device is fixedly stretched. The consol device 178a is fixed on the wall 9. The connecting means according to this variant further comprises a part 178b projecting from the consol device 178a arranged to support the first and second layers 1, 2 intended for solar energy absorption, the projection part 178b being carried through the first and second layers 1, 2.

According to this variant the locking means 179 comprises a locking element 179a in the form of a padlock or the corresponding, wherein the projecting part in the end projecting outside of the first layer 1 is configured to receive the locking element, wherein the locking element in locked position prevents removal of the part of the light absorbing device intended for solar energy absorption.

According to a variant the first and second layers are arranged to be supported by a projecting part 178b on each side in the upper area of the same, where said locking element 189a may be arranged on one of the projecting parts, alternatively on both projecting parts for locking of the light absorbing device.

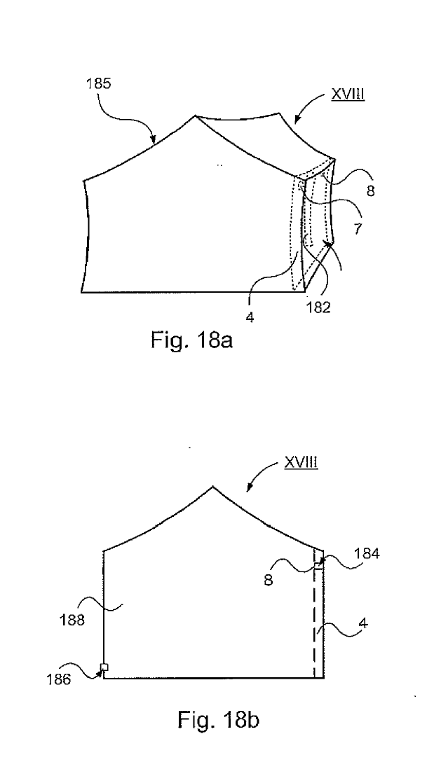

FIG. 18a schematically illustrate a perspective view of a building construction XVIII comprising/constituting a light absorbing device according to an embodiment of the present invention and FIG. 18b a side view of the building construction in FIG. 18a according to an eighteenth embodiment of the present invention.

According to this embodiment the light absorbing device XVIII according to an embodiment of the present invention constitutes a wall in an at least partly flexible building 185, e.g. a tent. Alternatively or in addition thereto the light absorbing device could constitute a roof in said at least partly flexible building 185, e.g. a tent.

The light absorbing device XVIII comprises a first and a second layer 1, 2 of which at least one is intended for solar energy absorption forming a space 4 there between in which air is arranged to flow for said heating, and means arranged to allow said flowing comprising an element configuration 182 arranged to divide the space 4 in a first subspace comprising an inlet opening 7 in the upper portion and a second subspace comprising an outlet opening 8, wherein at least one of said layer 1, 2 is flexible such that the surface exposed for solar energy absorption is reducible, hereby by simply pulling down the tent, wherein preferably both the first and second layers are flexible for said surface reduction.

Hereby the tent or the corresponding only needs to be pitched such that the wall and/or roof of the tent being provided with the light absorbing device are directed towards the sun.

According to a variant shown in FIG. 18b valve members are arranged for generating ventilation. Ventilation is according to a variant facilitated by arranging a first valve member 184 in connection to the outlet opening 8 and on an opposite wall of the building construction, preferably in the lower portion arranging a second valve member 186, wherein the first valve member 184 is arranged in a first position to allow flow through the outlet opening 8, e.g. flow from the space 4 and into the cavity 188 of the building construction, and in a second position closing the outlet opening and opening an opening to the surrounding such that the gaseous medium, here air, is allowed to flow out to the surrounding. The second valve member 186 is in a first position closed such that no air is allowed to flow through the same. The second valve member is in a second position arranged to allow air from the surrounding into the cavity 188 of the building construction.

The first position of the second valve member 186 is arranged to coincide with the first position of the first valve member 184 such that only air is allowed to flow through the inlet opening 7 via the space 4 and further through the outlet opening 8 back into the building construction, i.e. operate as a light absorbing device.

The second position of the valve member 186 is arranged to coincide with the second position of the first valve member 184 such that air is allowed to flow from the surrounding in through the second valve member 186 and via the cavity 188 of the building construction further through the first valve member 184 such that the cavity 188 in the building construction is ventilated.

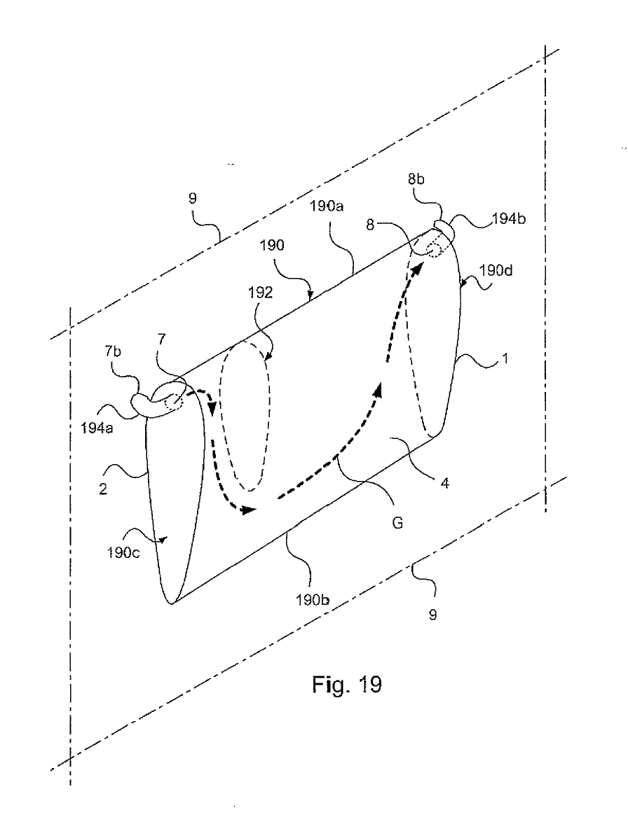

FIG. 19 schematically illustrates a perspective view of a light absorbing device according to a nineteenth embodiment XIX of the present invention.

The frame element 190 has an upper portion 190a, a lower portion 190b and a first and second side portion 190c, 190d.

The light absorbing device XI according to the nineteenth embodiment is intended to be arranged on a wall of a building.

The first and second side portion 190c, 190d are according to this embodiment constituted by a first side element 190c and a second side element 190d, to which the first and second layers 1, 2 are arranged to be connected such that the first and second side elements constitute gables of the light absorbing device XIX.

The first and second layers 1, 2 may according to a variant be constituted by a unit with a first opening in one end and a second opening in an opposite end, e.g. with a bas-like configuration with an opening in opposite ends, the first and second openings being adapted to receive the first and second side elements 190c, 190d, respectively. The first and second layers may alternatively be constituted by two separate parts arranged to be connected to said first and second side elements 190c, 190d. Thereby a tubular portion may be provided which then may be cut to a suitable length, which results in easy manufacturing of the light absorbing device.

The first and second side elements 190c, 190d are according to an embodiment removably connectable to the first and second layers 1, 2, according to a variant at said openings. The first and second side elements 190c, 190d are arranged to be connected by means of connecting means. said connecting means may be any suitable connecting means facilitating removable connection, such as Velcore© fastener, zipper, magnet or the corresponding.

According to an alternative embodiment the first and second side elements 190c, 190d are arranged to be fixedly connected to the first and second layers 1, according to a variant at said opening, wherein the connecting means may be any suitable connecting means e.g. in the form of fasteners such as rivets, screws, adhesives such as glue, or the corresponding.

The first and second side elements 190c, 190d also constitute spacer elements in that they separate the first and second layers 1, 2 with its extension.

The first and second side elements 190c, 190d may be any suitable material, said material preferably being weatherproof. The first and second side elements 190c, 190d are preferably rigid.

The first side element 190c comprises the inlet opening 7 and the second side element 190d comprises the outlet opening 8, i.e. the first side element 190c has an opening constituting the inlet opening 7, and the second side element 190d has an opening constituting the outlet opening 8.

The inlet opening 7 is arranged to be connected by means of a first pipe sleeve 194a or corresponding gas connection member for transport of a gaseous medium G, e.g. air, which connection in turn is intended to be attached to an opening 7b in the wall 9. The outlet opening 8 is arranged to be connected by means of a second pipe sleeve 114b or corresponding gas connection member for transport of a gaseous medium G, e.g. air, which connection in turn is intended to be attached to an opening 8b in the wall 9. By using side element according to the embodiment with openings constituting inlet opening and outlet opening respectively no holes are required in the second layer 2.

The element configuration 192 according to this embodiment constituting partition/guide of the gaseous medium G may be any suitable element configuration 192. The element configuration according to this embodiment also constitutes spacer element for assisting in keeping first and second layers 1, 2 separated. The element configuration according to this embodiment preferably has a similar shape as the first and second side elements 190c, 190d, and preferably extends substantially parallel to and at a distance from the first and second side elements from the upper portion 190c of the frame element in a direction towards and at a distance from the lower portion 190b of the frame element 190. The element configuration may according to a variant be sewed in, according to another variant inflatable.

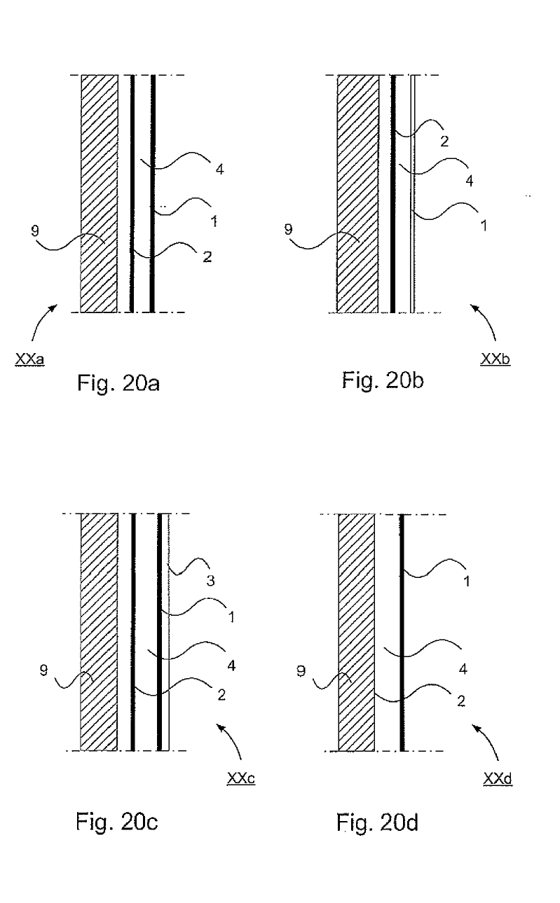

FIG. 20a-d schematically illustrate a side view of a part of a light absorbing device XXa, XXb, XXc, XXd according to twentieth embodiments of the present invention.

FIG. 20a show a side view of a part of a light absorbing device XXa according to an embodiment of the present invention. According to this embodiment both the first and second layers 1, 2 are dark or black, wherein both layers have solar energy absorption properties, the surface of the first layer 1 during use is heated up by absorption of light rays for heating of the flowing medium in the space 4 between said layers 1, 2. The first layer 1 is here flexible such that the surface intended for solar energy absorption is reducible. In FIG. 20a the device XXa is arranged at a wall 9.

FIG. 20b shows a side view of a part of a light absorbing device XXb according to an embodiment of the present invention. According to this embodiment the first layer is transparent and the second layer is dark or black wherein the second layer 2 has solar energy absorption properties for heating of the flowing medium in the space 4 between said layers 1, 2, the surface of the second layer 2 during use being heated by absorption of light rays passing the transparent first layer 1 and by the heated second layer 2. The second layer 2 is here flexible such that the surface intended for solar energy absorption is reducible. According to a variant the first layer is also flexible such that its surface is reducible. In FIG. 20b the device XXb is arranged at a wall. According to a variant according to the fifteenth embodiment in FIG. 15 the transparent first layer is rigid and is constituted by e.g. glass. By having a transparent first layer 1 and a solar energy absorbing second layer 2 a more efficient heating of the medium is obtained, and thus increased efficiency of the device.

FIG. 20c shows a side view of a part of a light absorbing device XXc according to an embodiment of the present invention. FIG. 20c differs from FIG. 20a in that the device in addition to the first and second layer 1, 2 comprises a third transparent layer 3 arranged externally to the first layer 1 wherein the space 4 is delimited by the first and second layer with the third layer 3 external to the first layer 1. The third layer 3 is according to a variant flexible such that its surface is reducible. According to a variant the third layer is removably arranged to the first layer 1. The third layer 3 is according to a variant removably connected to the first layer 1 by means of a zipper. According to another variant the third layer 3 is removably connected to the first layer 1 by means of a Velcro© fastener. The third layer 3 may be arranged externally to the first layer 1 and removably connected to the second layer 2, or removably connected in another way in the device, such as removably connected to the frame element where it does not comprise the first or second layer. Thereby the transparent third layer 3 may be replaced or removed for cleaning and then reattached if it e.g. has become dirty such that the efficiency is impaired. According to another variant the third layer 3 is rigid, e.g. glass. By arranging a third layer 3 externally to the solar energy absorbing first layer 1 an insulating effect is obtained wherein a more efficient heating of the medium is facilitated and thus increased efficiency of the device.

FIG. 20d show a side view of a part of a light absorbing device XXd according to an embodiment of the present invention. FIG. 20d differs from FIG. 20a in that the second layer here is constituted by the wall 9 of a house or the corresponding as described in connection to FIG. 16. The first layer is here flexible such that the surface intended for solar energy absorption is reducible.

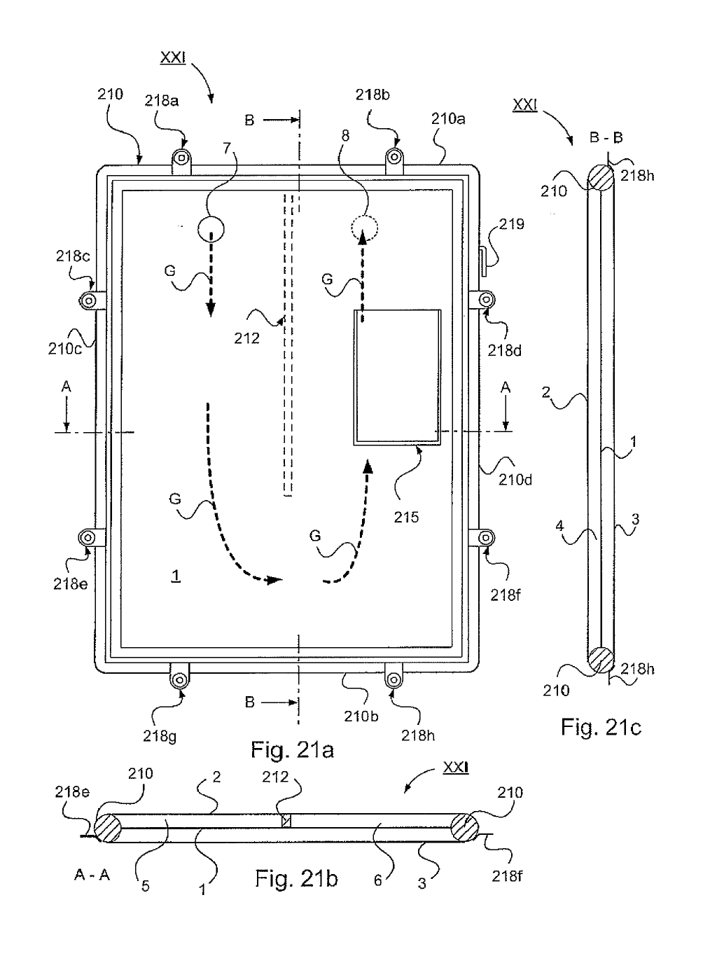

FIG. 21a-c schematically illustrate the light absorbing device XXI according to a twenty-first embodiment of the present invention.

The light absorbing device XXI comprises a first and second layer 1, 2 of which at least one is intended for solar energy absorption and has a surface exposed for solar energy absorption. The first and second layers form a space 4 there between, in which a gaseous medium G preferably air is arranged to flow for said heating. Preferably a fan is used for allowing said flowing.

The light absorbing device comprises an inlet opening 7 and an outlet opening 8 between which said medium is arranged to be flown and intended to heat a room in connection to the light absorbing device. The inlet opening 7 and outlet opening 8 are arranged at a distance from each other in the upper portion of the second layer, i.e. the inner layer.

The frame element 210 of the device according to this embodiment has a substantially rectangular shape wherein the upper portion 210a and the lower portion 210b has an extension being shorter than the extension of the side portions 210c, 210d, when the device is in its active position or operating position, i.e. arranged on an outer wall or the corresponding. The device XXI has during use a substantially rectangular and vertically elongated shape. The frame element 210 of the device according to this embodiment further has a substantially circular cross-section.

The inlet opening 7 and outlet opening 8 are arranged substantially at the same distance from the upper portion of the frame element. The inlet opening 7 is arranged at substantially the same distance from the left portion 210c of the frame element as the outlet opening 8 is arranged from the right portion 210d of the frame element.

The frame element 210 has according to this embodiment a channel 211 for insertion of a gaseous medium, preferably air, for separation of the first and second layers 1, 2. The device comprises a valve 219 for filling of the gaseous medium G, which valve is constituted by a charging valve, which may also include a pressure relief valve.

The element configuration 212 constituting the partition/guide of the gaseous medium G according to this embodiment has an extension between its upper end being connected to an upper portion 210a of the frame element 20 and its lower end situated at a distance from a lower portion 210b of the frame element 210. The element configuration 212 has according to this embodiment a straight extension, i.e. is extending substantially perpendicular from the upper portion 210a of the frame element 210. The element configuration extends according to this embodiment over more than half the distance between upper and lower portion of the frame element 20. The element configuration 212 is preferably connected to the upper portion 20a of the frame element 20.

The element configuration 212 is arranged substantially central such that it divides the space 4 in a first subspace 5 and a second subspace 6 being essentially as big as the first subspace 5. The element configuration/partition 212 is according to a variant constituted by a hard material such as a plastic material.

The device further comprises fasteners 218a, 218b, 218c, 218d, 218e, 218f, 218g, 218h, for attachment on a wall or the corresponding. The fasteners are arranged in connection to the frame element 210. According to this embodiment two fasteners are arranged at a distance from each other on the respective side of the frame element. The fasteners are arranged such that the light absorbing device XXI may be suspended and fixated on e.g. a wall.

The device according to this embodiment comprises a third transparent layer 3 arranged externally to the first layer 1 wherein the space 4 is delimited by the first and second layers with the third layer 3 external to the first layer 1. The third layer is arranged such that an insulating effect occurs.

The device according to this embodiment further comprises a pocket 215 intended for solar cells. The pocket is arranged, according to a variant arranged by welding, on the first layer 1. By introducing solar cells in the pocket use of a solar cell for e.g. operation of a fan for providing of said flowing of air in the space 4 is facilitated.

Above different embodiments of the present invention has been described. According to an embodiment of the light absorbing device for heating a medium by means of solar energy according to the present invention, comprising a first and a second layer of which at least one is intended for solar energy absorption forming a space 4 there between in which a liquid medium L is arranged to flow for said heating and means, e.g. a pump device, arranged to allow said flowing, wherein at least one of said layer is flexible such that the surface exposed to solar energy is reducible. Hereby the medium is constituted by only a liquid medium L such as water, wherein the space 4 is constituted by a liquid tight channel having at least one inlet opening and at least one outlet opening. Hereby no element configuration/partition is required.

According to another variant the medium is constituted by a gaseous medium G such as air and the means for flowing the gaseous medium G by a fan, wherein said flowing of the gaseous medium G may be provided without element configuration.

The first and second layers 1, 2 according to the embodiment in FIGS. 2-18 and 20-21 are according to an embodiment essentially parallel. The first and second layers 1, 2 are according to the embodiments in FIGS. 1 and 19 none parallel. The first and second layers 1, 2 may be mutually arranged at a distance from each other for forming of said space 4 in any suitable manner, and may among others depend on solar angle and the character of the building.

The first and/or second layer of the light absorbing device according to the present invention is according to a variant composed of a material with solar energy absorbing properties. The first and/or second layers of the light absorbing device according to the present invention is according to a variant composed of a material with flexible properties such that the surface of said layer is reducible. The material of the first and/or second layer is e.g. textile, woven fabric, fibre, rubber or the corresponding. According to a variant said material is constituted by black-/dark-coloured silicon coated woven fabric. According to a variant said material is constituted by dark, preferably black PVC.

The light absorbing device is according to an embodiment granular, rough and/or matt which results in the advantage that the absorption area increases.

The first and second layers 1, 2 of the light absorbing device according to the present invention may be connected in any suitable manner. Said connection may e.g. be provided in that the first and second layers 1, 2 are sewn together, glued together, welded together, heated together, connected by Velcro© fastener, zipper, magnet or the corresponding for forming of said edge. According to a variant the first and second layers 1, 2 are constituted by the same flexible material piece, wherein said material piece is folded such that said first and second layers are formed. Said connection is according to a variant constituted by a separate frame element to which said layers are connected.

The inlet opening and outlet opening of the light absorbing device according to the present invention are, as described above and shown in the embodiments above, arranged in the upper area of the second layer, wherein said gaseous medium G is arranged to flow between said inlet opening and said outlet opening. By arranging the openings in the upper area self circulation of the gaseous medium G is improved. When using a fan for providing of said flow, the inlet opening and outlet opening may be arranged on an arbitrary area of the second layer.

According to the embodiment with reference to FIG. 18b the light absorbing device comprises valve members. Any of the embodiments in FIG. 1-21 of the light absorbing device according to the present invention may be provided with the corresponding valve member. Consequently, according to an embodiment the light absorbing device according to any of the embodiments of the present invention comprises a valve member arranged in connection to said outlet opening to in a first position allow flowing through the outlet opening into a cavity connected to the outlet opening, which according to a variant is constituted by a room/space in a building, and in a second position preventing flowing through the outlet opening but allowing flow out of said cavity to the surrounding, wherein in said second position of the valve member ventilation of said cavity via said space is arranged to be provided. Hereby is facilitated apart from heating of the gaseous medium, here air, to also use the light absorbing device such that the air may be heated when so required and ventilation of air through the cavity, e.g. room in a building construction may occur when there is a need for this.

The light absorbing device according to the present invention may have any suitable size of the surface for solar energy absorption. According to a variant the surface is within the range 1 m² to 40 m², preferably 2-20 m², preferably 4-12 m². The advantage with a surface within the range 4-12 m² is that relatively large surface for solar energy absorption is obtained, suitable for e.g. covering at least a part of a wall of a building, at the same time as the web in the space 4 through which the gaseous medium G is to be transported may be adapted for efficient self circulation. A surface in said range also results in a relatively easy handling of the device. According to a variant of the invention the size of the surface for solar energy absorption is in the range of 1.5 m² to 3 m². This has among other the advantage that the device becomes easier to handle, easier to place e.g. on a wall of a house, and results in high efficiency per surface unit.

The distance between the first and second layers 1, 2 is among others depending on the surface of the same, the distance increasing with the size of the surface.

The light absorbing device according to the present invention as described with reference to the above mentioned embodiments is arranged to heat a gaseous medium, here air, by means of solar energy. The light absorbing device comprises a first and second layer 1, 2, of which at least one is intended for solar energy absorption and has a surface exposed for solar energy absorption. The first and second layers form a space 4 there between, in which the air G is arranged to flow for said heating, the air being arranged to flow between an inlet opening and an outlet opening and arranged to heat a room in connection to the light absorbing device. Preferably a fan is used for allowing said flowing.

The inventive idea is that at least said layer 1, 2 intended for solar energy absorption of the light absorbing device is flexible such that the surface exposed for solar energy absorption is reducible between an active solar energy absorbing position in which the surface exposed for solar energy absorption of the layer 1, 2 intended for solar energy absorption is arranged to receive solar energy, and a passive position in which the surface exposed for solar energy absorption of the layer 1, 2 intended for solar energy absorption is reduced compared to the surface in the active position.

Said reduction of the surface of the flexible layer 1, 2 exposed for solar energy absorption is e.g. performed during non-operation of the device. Said reduction is provided e.g. by rolling up, folding and/or wrapping of said flexible layers 1, 2. It may be both layers that are flexible in this way such as the embodiments according to FIGS. 1-14, 17-19 and 21, wherein preferably the entire device is removably arranged during non-operation such that it may be folded together or the corresponding, or only the layer intended for solar energy absorption such as in the embodiments according to FIGS. 15 and 16 such that the flexible layer may be rolled up, pleated together during non-operation such that it does not occupy unnecessary space on e.g. a house wall.

The foregoing description of the preferred embodiments of the present invention has been provided for the purposes of illustration and description. It is not intended to be exhaustive or to limit the invention to the precise forms disclosed. Obviously, many modifications and variations will be apparent to practitioners skilled in the art. The embodiments were chosen and described in order to best explain the principles of the invention and its practical applications, thereby enabling others skilled in the art to understand the invention for various embodiments and with the various modifications as are suited to the particular use contemplated.

1. A light absorbing device for heating a medium by means of solar energy, comprising a first and second layer (1, 2) of which at least one is intended for solar energy absorption, forming a space (4) there between in which a first medium (G; L) is arranged to flow for said heating, and means arranged to allow said flowing, characterized in that at least one of said layers (1, 2) is flexible such that the surface exposed for solar energy absorption is reducible.

2. A light absorbing device according to claim 1, comprising at least one inlet opening (7) and at least one outlet opening (8), wherein said medium (G; L) is arranged to flow between said inlet opening (7) and said outlet opening (8).

3. A light absorbing device according to claim 2, wherein said flowing means comprises an element configuration (12; 22; 32; 42; 52; 72; 82; 92; 102; 112; 132; 152; 162; 182) arranged to divide the space (4) in at least one first subspace (5) comprising said inlet opening (7) and a second subspace (6) comprising said outlet opening (8).

4. A light absorbing device according to any of claims 1-3, wherein comprises a frame element (10; 20; 70; 80; 90; 100; 110; 150; 160; 190) arranged to delimit the space between said first and second layer (1, 2).

5. A light absorbing device according to claim 3 or 4, wherein said element configuration (22; 32; 42; 52; 62; 92) comprises at least one confined channel (23; 33; 43; 53; 93).

6. A light absorbing device according to claim 4 or 5, wherein said frame element (20) comprises at least one confined channel (21).

7. A light absorbing device according to claim 6, wherein at least one channel of the element configuration and at least one channel of the frame element are in fluid connection with each other.

8. A light absorbing device according to any of claims 3-7, wherein said element configuration comprises from said frame element separated elements arranged in such a way in the space (4) that the surface exposed to solar energy is foldably reducible.

9. A light absorbing device according to any of claims 1-8, comprising spacer means for separating said first and second layer.

10. A light absorbing device according to claim 6, wherein said spacer means comprises channel insertion means.

11. A light absorbing device according to claim 10, wherein said channel insertion means comprises a gaseous medium, e.g. air, arranged to be introduced and pressurized in at least one channel of the element configuration and/or at least one channel of the frame element.

12. A light absorbing device according to claim 10 or 11, wherein said channel insertion means comprises spacer elements arranged to be introduced in at least one channel of the element configuration and/or at least one channel of the frame element.

13. A light absorbing device according to any of claim 9-12, wherein said spacer means comprises resilient means (74; 84; 94; 104).

14. A light absorbing device according to claim 13, wherein said resilient means comprises at least one spring member arranged in said space to provide a spring action between a compressed state and an expressed state for separation of first and second layers (1, 2), wherein the surface exposed for solar energy absorption is reducible at least in said compressed state.

15. A light absorbing device according to claim 14, wherein said spring member is ring-shaped, preferably circular.

16. A light absorbing device according to claim 15, comprising at least two spring members arranged by each other in said space such that in said compressed state said spring members are foldable over each other for said reduction of the surface exposed for solar energy absorption.

17. A light absorbing device according to any preceding claims, wherein the device is arranged to be attached to a surface having an inclination relative to the horizontal plane, e.g. a wall, wherein the device comprises surface reduction means for reducing the surface exposed for solar energy absorption when the device is attached to said surface.

18. A light absorbing device according to claim 17, wherein said surface reduction means comprises a roll device for unrollable rolling up of said surface exposed for solar energy absorption.

19. A light absorbing device according to claim 17, wherein said surface reduction means comprises a retracting device for extensible pleatable retraction of said surface exposed for solar energy absorption.

20. A light absorbing device according to any preceding claims, wherein said first medium is a gaseous medium, preferably air.

21. A light absorbing device according to any preceding claims, wherein said first medium is a liquid medium, preferably water.

22. A light absorbing device according to any preceding claims, further comprising a second medium separated from said first medium arranged to flow in channels in said space for said heating, between at least one second inlet opening and at least one second outlet opening.

23. A light absorbing device according to any preceding claims, further comprising a transparent third layer arranged externally to the first layer.

24. A light absorbing device according to any preceding claims, wherein said flowing means comprises an electric device, e.g. a fan device and/or a pump device.

25. A light absorbing device according to claim 22, comprising at least one solar cell element for driving said electric device.

26. A light absorbing device according to any preceding claims, comprising a valve member arranged in connection to said outlet opening to in a first position allow flowing through the outlet opening into a cavity connected to the outlet opening and in a second position prevent flowing through the outlet opening but allowing flowing out of said cavity to the surrounding.

27. A light absorbing device according to claim 26, wherein ventilation of the cavity via said space is arranged to be provided in said second position of the valve member.

28. A building construction which is at least partly flexible, e.g. a tent, comprising a light absorbing device according to any of said embodiments wherein said light absorbing device constitutes at least one wall and/or roof in said building construction.
